(19) United States
(12) Patent Application Publication
(10) Pub. No.: US 2025/0143159 A1
(43) Pub. Date: May 1, 2025

(54) DISPLAY APPARATUS

(71) Applicant: Samsung Display Co., LTD., Yongin-si (KR)

(72) Inventors: Jiwon LEE, Yongin-si (KR); Kyungmin KIM, Yongin-si (KR); Heonjung SHIN, Yongin-si (KR); Gyujeong LEE, Yongin-si (KR)

(21) Appl. No.: 18/884,437

(22) Filed: Sep. 13, 2024

(30) Foreign Application Priority Data
Oct. 26, 2023 (KR) 10-2023-0145081

(51) Int. Cl. H10K 77/10; H10K 102/00

(52) U.S. Cl. CPC H10K 77/111; H10K 2102/311

(57) ABSTRACT

A display apparatus includes a substrate including island areas and bridge areas, where each of the bridge areas has a serpentine shape and connects adjacent island areas to each other, a first line arranged in the bridge area, and a first insulating layer disposed on the first line, where a plurality of groove patterns is defined in the bridge areas by the first insulating layer.

This application claims priority to Korean Patent Application No. 10-2023-0145081, filed on Oct. 26, 2023, and all the benefits accruing therefrom under 35 U.S.C. § 119, the content of which in its entirety is herein incorporated by reference.

### BACKGROUND

### 1. Field

One or more embodiments relate to a display apparatus, and more particularly, to a flexible display apparatus.

### 2. Description of the Related Art

With the development of display apparatuses for visually displaying electrical signals, various display apparatuses with desired characteristics, such as small thickness, small weight, reduced power consumption, etc., have been introduced. For example, flexible display apparatuses which may be folded or rolled have been introduced. Recently, display apparatuses of various structures, such as stretchable display apparatuses, which may be changed to have various shapes, have been actively researched and developed.

### SUMMARY

One or more embodiments include a display apparatus, for example, a flexible display apparatus.

According to one or more embodiments, a display apparatus includes a substrate including island areas and bridge areas, where each of the bridge areas has a serpentine shape and connects adjacent island areas to each other, a first line arranged in the bridge area, and a first insulating layer disposed on the first line, where groove patterns are defined in the bridge area by the first insulating layer.

In an embodiment, each of the bridge areas may include two round portions, a straight-line portion between the two round portions, and connection portions between the two round portions and the island areas.

In an embodiment, each of the two round portions may include an inner edge and an outer edge, and the groove patterns may include first groove patterns arranged along the inner edge.

In an embodiment, the display apparatus may further include a second insulating layer arranged in the island area, where second groove patterns may be defined in the island areas by the second insulating layer to be adjacent to the bridge areas.

In an embodiment, the second groove patterns may be arranged along an edge of the island area.

In an embodiment, the groove patterns may further include third groove patterns arranged in the straight-line portion and the connection portions.

In an embodiment, the third groove patterns may be arranged along both opposing side edges of the bridge area.

In an embodiment, each of the first groove patterns may have a first width in an extension direction of the bridge area, each of the third groove patterns may have a second width in the extension direction of the bridge area, and the first width may be different from the second width.

In an embodiment, each of the two round portions may include an inner edge and an outer edge, and the first line may be arranged to be closer to the outer edge than to the inner edge.

In an embodiment, the display apparatus may further include a third insulating layer disposed below the first line, and each of the groove patterns may be defined by an opening defined in the first insulating layer and an opening defined in the third insulating layer.

In an embodiment, each of the groove patterns may be defined by the opening defined in the first insulating layer, the opening defined in the third insulating layer, and an opening defined in the substrate.

In an embodiment, each of the groove patterns may have a width in an extension direction of the bridge area, where the width increases as being toward an edge of the bridge area.

In an embodiment, each of the groove patterns may have a width in an extension direction of the bridge area, where the width decreases as being toward an edge of the bridge area.

In an embodiment, in a plan view, each of the groove patterns may have a round edge.

In an embodiment, an edge of the first line may have a concavo-convex portion.

In an embodiment, the display apparatus may further include a third insulating layer disposed below the first line and a second line disposed below the third insulating layer, where an edge of the second line may have a concavo-convex portion.

In an embodiment, the first insulating layer may include an organic insulating material or an inorganic insulating material.

According to one or more embodiments, a display apparatus including a display area and a non-display area outside the display area includes a substrate including island areas and bridge areas, where each of the bridge areas has a serpentine shape and connects adjacent island areas to each other, a first line arranged in the bridge area, and a first insulating layer disposed on the first line, where groove patterns are in the bridge areas defined by the first insulating layer, and groove patterns arranged in one of the bridge areas have different shapes from groove patterns arranged in another of the bridge areas.

In an embodiment, the non-display area may include a first sub-non-display area and a second sub-non-display area between the first sub-non-display area and the display area, and an elongation rate of the first sub-non-display area may be greater than an elongation rate of the second sub-non-display area.

In an embodiment, an elongation rate of the display area may be equal to or greater than an elongation rate of the non-display area.

In an embodiment, the display area may include at least one first area and a second area outside the at least one first area, and an elongation rate of the at least one first area may be greater than an elongation rate of the second area.

In an embodiment, an edge of the first line may have a concavo-convex portion in the at least one first area.

In an embodiment, the display area may have a protrusion portion protruding from a peripheral portion in a thickness direction, and the at least one first area may be arranged to surround at least a portion of the protrusion portion.

In an embodiment, the at least one first area may have a loop shape surrounding the protrusion portion.

In an embodiment, the at least one first area may have a triangular shape having one vertex toward a center of the protrusion portion.

### BRIEF DESCRIPTION OF THE DRAWINGS

The above and other features of certain embodiments of the disclosure will be more apparent from the following description taken in conjunction with the accompanying drawings, in which:

FIG. 1 is a schematic perspective view of a display apparatus according to an embodiment;

FIGS. 2A and 2B are perspective views showing the display apparatus of FIG. 1 stretched in a first direction;

FIG. 2C is a perspective view showing the display apparatus of FIG. 1 stretched in a second direction;

FIG. 2D is a perspective view showing the display apparatus of FIG. 1 stretched in a first direction and a second direction;

FIG. 2E is a perspective view showing the display apparatus of FIG. 1 stretched in a third direction;

FIG. 3 is a schematic plan view of a display apparatus according to an embodiment;

FIG. 4 is an enlarged plan view of a portion of a display apparatus, corresponding to region IV of FIG. 3, according to an embodiment;

FIG. 5 is a schematic cross-sectional view of a first island portion and a first bridge portion which are arranged in a display area of a display apparatus according to an embodiment;

FIGS. 6A to 6C are each an equivalent circuit diagram of a sub-pixel of a display apparatus according to an embodiment;

FIGS. 7A and 7B are each a schematic cross-sectional view of an emission element of a display apparatus according to an embodiment;

FIG. 8A is a schematic plan view of one first bridge portion and an area adjacent to the first bridge portion which are included in a display apparatus according to an embodiment;

FIGS. 8B to 8D are schematic cross-sectional views of a first bridge portion according to an embodiment;

FIG. 9A is a schematic plan view of one first bridge portion included in a display apparatus and an area adjacent to the first bridge portion, according to an embodiment;

FIGS. 9B to 9D are schematic cross-sectional views of a first island portion according to an embodiment;

FIG. 10A is a schematic plan view of one first bridge portion and an area adjacent to the first bridge portion which are included in a display apparatus according to an embodiment;

FIGS. 10B to 10D are schematic cross-sectional views of a first bridge portion according to an embodiment;

FIGS. 11A to 11C are schematic plan views of one first bridge portion and an area adjacent to the first bridge portion which are included in a display apparatus according to an embodiment;

FIGS. 12A to 12F are schematic plan views of a portion of a first bridge portion according to an embodiment;

FIG. 13A is a schematic plan view of one first bridge portion and an area adjacent to the first bridge portion which are included in a display apparatus according to an embodiment;

FIGS. 13B and 13C are schematic cross-sectional views of a first bridge portion according to an embodiment;

FIGS. 14A and 14B are plan views of one first bridge portion and an area adjacent to the first bridge portion which are included in a display apparatus according to an embodiment;

FIGS. 15A to 15D are schematic plan views of a display apparatus according to an embodiment; and

FIGS. 16A to 16G are each a schematic perspective view of an electronic apparatus including a display apparatus according to an embodiment.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

While the disclosure is capable of various modifications and alternative forms, embodiments thereof are shown by way of example in the drawings and will herein be described in detail. Effects and characteristics of the disclosure and methods of achieving the same will become apparent by referring to the embodiments described in detail below along with the drawings. However, the disclosure is not limited to the embodiments disclosed hereinafter and may be realized in various forms.

It will be understood that although the terms “first,” “second,” etc. may be used herein to describe various components, these components should not be limited by these terms. These components are only used to distinguish one component from another.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. Throughout the disclosure, the expression “at least one of a, b or c” or “at least one selected from a, b and c” indicates only a, only b, only c, both a and b, both a and c, both b and c, all of a, b, and c, or variations thereof.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that when a layer, region, or element is referred to as being formed “on” another layer, area, or element, it can be directly or indirectly formed on the other layer, region, or element. That is, for example, intervening layers, regions, or elements may be present.

In this specification, it will be understood that when an element, an area, or a layer is referred to as being connected to another element, area, or layer, it can be directly and/or indirectly connected to the other element, area, or layer. For example, it will be understood in this specification that when an element, an area, or a layer is referred to as being in contact with or being electrically connected to another element, area, or layer, it can be directly and/or indirectly in contact with or electrically connected to the other element, area, or layer.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

In this specification, the x-axis, the y-axis and the z-axis may not be limited to three axes of a rectangular coordinate system and may be interpreted in a broader sense. For example, the x-axis, the y-axis, and the z-axis may be perpendicular to one another, or may represent different directions that are not perpendicular to one another.

In this specification, when a certain embodiment may be implemented differently, a specific process order may be performed differently from the described order. For example, two consecutively described processes may be performed substantially at the same time or performed in an order opposite to the described order.

Sizes of elements in the drawings may be exaggerated for convenience of explanation. For example, sizes and thicknesses of the elements in the drawings are randomly indicated for convenience of explanation, and thus, the disclosure is not necessarily limited to the illustrations of the drawings.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described in detail with reference to the accompanying drawings, where the same or corresponding elements are denoted by the same reference numerals throughout, and any repetitive detailed description thereof may be omitted or simplified.

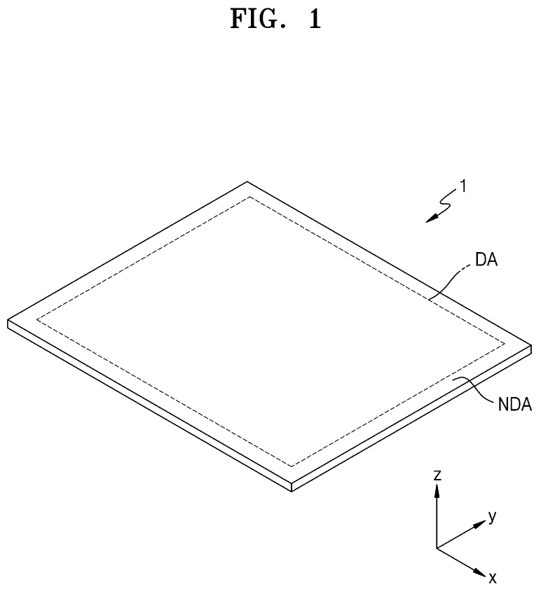

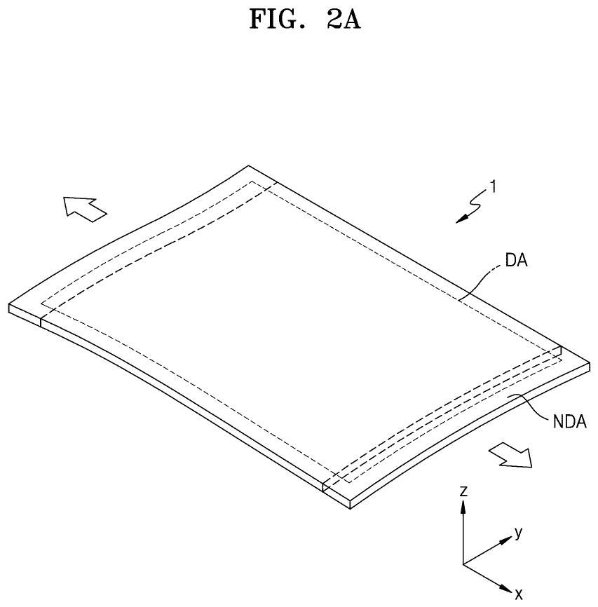

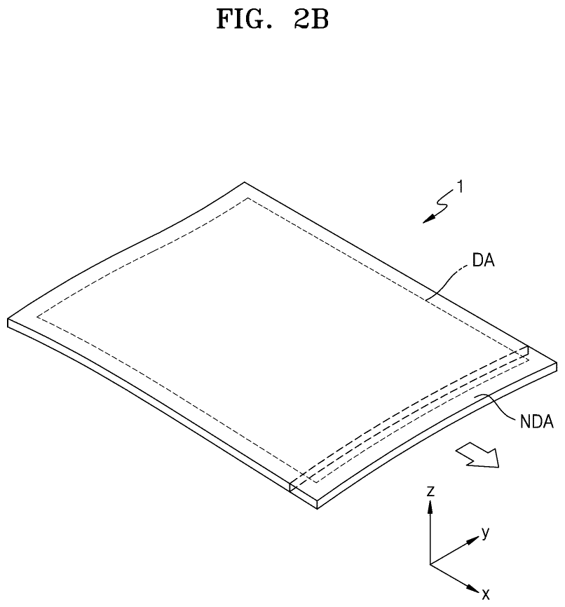

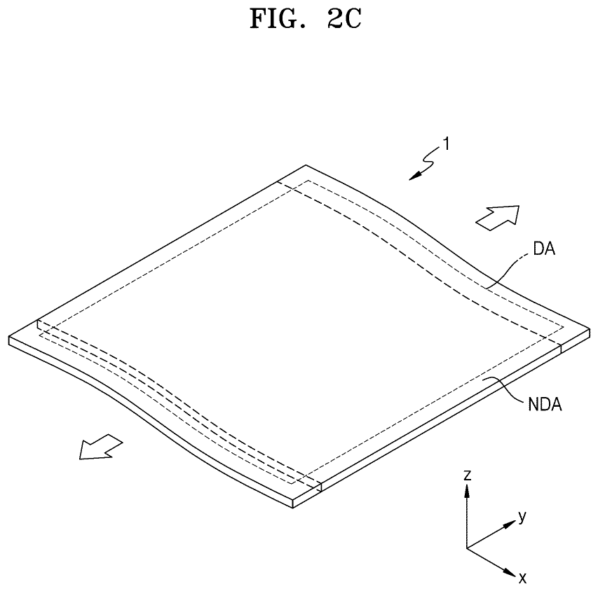

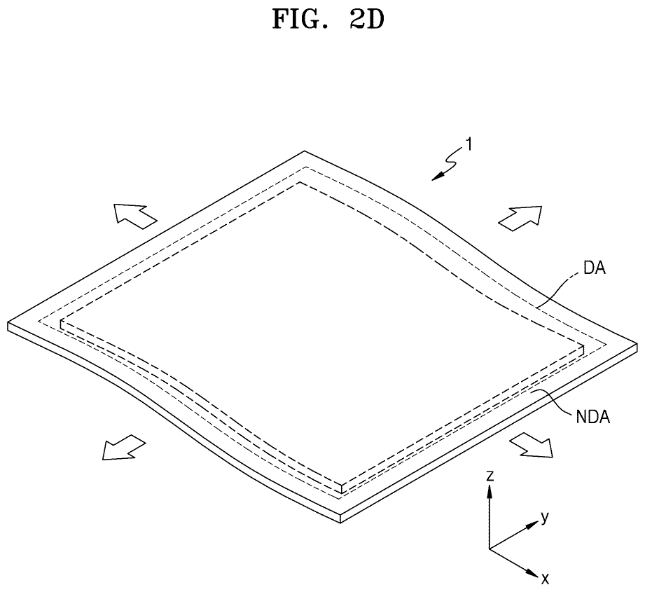

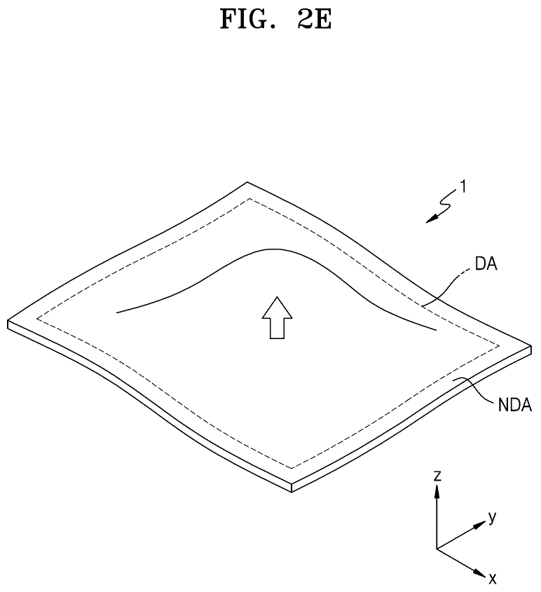

FIG. 1 is a schematic perspective view of a display apparatus 1 according to an embodiment. FIGS. 2A and 2B are perspective views showing the display apparatus 1 of FIG. 1 stretched in a first direction. FIG. 2C is a perspective view showing the display apparatus 1 of FIG. 1 stretched in a second direction. FIG. 2D is a perspective view showing the display apparatus 1 of FIG. 1 stretched in the first direction and the second direction. FIG. 2E is a perspective view showing the display apparatus 1 of FIG. 1 stretched in a third direction.

Referring to FIG. 1, an embodiment of the display apparatus 1 may include a display area DA and a non-display area NDA. The display area DA may include a plurality of pixels. The display apparatus 1 may provide a certain image by using light emitted from the plurality of pixels. The non-display area NDA may be arranged outside the display area DA. The non-display area NDA is an area in which pixels are not arranged, and the non-display area NDA may entirely surround the display area DA.

The display apparatus 1 may be stretched or shrunk in various directions. The display apparatus 1 may be stretched in the first direction (for example, an x direction and/or a −x direction) by an external force applied by an external object or a user. According to an embodiment, as illustrated in FIGS. 2A and 2B, the display area DA and/or the non-display area NDA of the display apparatus 1 may be stretched in the first direction (for example, the x direction and/or the −x direction). For example, as illustrated in FIG. 2A, the display apparatus 1 may be stretched in the x direction and the −x direction, or as illustrated in FIG. 2B, the display apparatus 1 may be stretched in the x direction while a side of the display apparatus 1 is being fixed.

The display apparatus 1 may be stretched in the second direction (for example, a y direction and/or a −y direction) by an external force applied by an external object or a user. According to an embodiment, as illustrated in FIG. 2C, the display area DA and/or the non-display area NDA of the display apparatus 1 may be stretched in the y direction and the −y direction. According to another embodiment, the display apparatus 1 may be stretched in the y direction and the −y direction while a side of the display apparatus 1 is being fixed.

The display apparatus 1 may be stretched in a plurality of directions, for example, the first direction (for example, the x direction and/or the −x direction) and the second direction (for example, the y direction and/or the −y direction), by an external force applied by an external object or a part of a human body. As illustrated in FIG. 2D, the display area DA and/or the non-display area NDA of the display apparatus 1 may be stretched in the +x directions and the ty directions.

The display apparatus 1 may be stretched in the third direction (for example, a z direction or a −z direction) by an external force applied by an external object or a part of a human body. According to an embodiment, FIG. 2E illustrates that a portion of the display apparatus 1, for example, a region of the display area DA, may protrude in the z direction. According to another embodiment, a portion of the display apparatus 1, for example, a region of the display area DA, may protrude in the −z direction (or may be recessed from the z direction).

FIGS. 2A to 2E illustrate an embodiment where the display apparatus 1 may be stretched in the first direction, the second direction, and/or the third direction. However, the disclosure is not limited thereto. According to another embodiment, the display apparatus 1 may be variously transformed to have amorphous shapes, such as a shape that is bent or twisted with respect to two or more axes, etc.

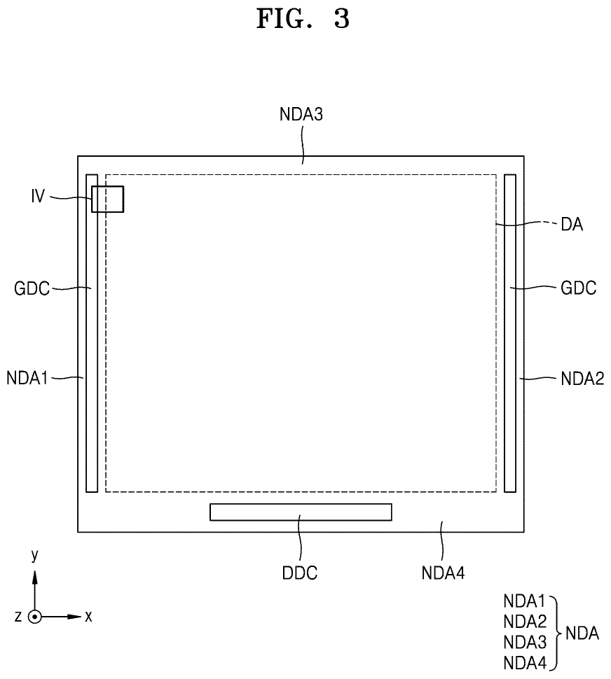

FIG. 3 is a schematic plan view of the display apparatus 1 according to an embodiment.

In an embodiment, a plurality of pixels may be arranged in the display area DA of the display apparatus 1. Each pixel may include sub-pixels emitting light of different colors. An emission element corresponding to each sub-pixel may be arranged in the display area DA. A circuit configured to provide an electrical signal to the emission elements and transistors electrically connected to the emission elements, the emission elements and the transistors being arranged in the display area DA, may be arranged in the non-display area NDA around the display area DA. A gate driving circuit GDC may be arranged in each of a first non-display area NDA1 and a second non-display area NDA2 which are arranged at both opposing sides of the display area DA with the display area DA therebetween. The gate driving circuit GDC may include drivers configured to provide an electrical signal to gate electrodes respectively included in the transistors electrically connected to the emission elements. FIG. 3 illustrates an embodiment where the gate driving circuit GDC may be arranged in each of the first non-display area NDA1 and the second non-display area NDA2. However, the disclosure is not limited thereto. According to another embodiment, the gate driving circuit GDC may be arranged in one of the first non-display area NDA1 and the second non-display area NDA2.

A data driving circuit DDC may be arranged in a third non-display area NDA3 and/or a fourth non-display area NDA4 connecting the first non-display area NDA1 with the second non-display area NDA2. FIG. 3 illustrates an embodiment where the data driving circuit DDC may be arranged in the fourth non-display area NDA4. However, the disclosure is not limited thereto. According to another embodiment, the data driving circuit DDC may be arranged in each of the third non-display area NDA3 and the fourth non-display area NDA4.

FIG. 3 illustrates an embodiment where the data driving circuit DDC may be arranged in the fourth non-display area NDA4 of the display apparatus 1. However, the disclosure is not limited thereto. According to another embodiment, the display apparatus 1 may further include a flexible circuit board (not shown) electrically connected to the display apparatus 1 through a terminal portion (not shown) arranged in the fourth non-display area NDA4, and the data driving circuit DDC may be arranged on this flexible circuit board.

According to some embodiments, an elongation rate of the non-display area NDA may be equal to or less than an elongation rate of the display area DA. According to an embodiment, the elongation rate of the non-display area NDA may be different for each region of the non-display area NDA. For example, the first non-display area NDA1, the second non-display area NDA2, and the third non-display area NDA3 may have substantially the same elongation rate as one another, but the elongation rate of the fourth non-display area NDA4 may be less than the elongation rate of each of the first non-display area NDA1, the second non-display area NDA2, and the third non-display area NDA3.

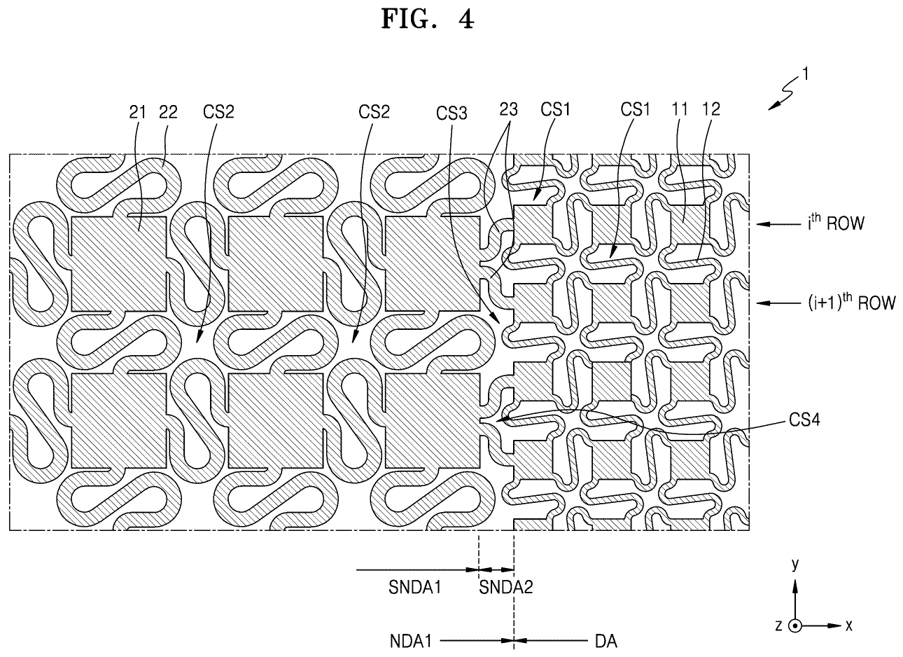

FIG. 4 is an enlarged plan view of a portion of the display apparatus 1, corresponding to region IV of FIG. 3, according to an embodiment.

Referring to FIG. 4, an embodiment of the display apparatus 1 may include first island portions 11 and first bridge portions 12 in the display area DA, wherein the first island portions 11 may be apart from each other in a first direction (for example, an x direction or an −x direction) and a second direction (for example, a y direction or a −y direction), and the first bridge portions 12 may connect the first island portions 11 that are adjacent to each other.

The first bridge portions 12 may be arranged to be spaced apart from each other by a first opening portion CS1 located or defined between the first bridge portions 12. The first bridge portions 12 may have a serpentine shape. In an embodiment, for example, as illustrated in FIG. 4, the first bridge portions 12 may have a S-like shape, i.e., approximately have a shape of the letter “S” of the alphabet.

Each first island portion 11 may be connected to the plurality of first bridge portions 12. In an embodiment, for example, each first island portion 11 may be connected to four first bridge portions 12. Two first bridge portions 12 may be arranged at both opposing sides of the first island portion 11 in the first direction (for example, the x direction or the −x direction), and the rest two first bridge portions 12 may be arranged at both opposing sides of the first island portion 11 in the second direction (for example, the y direction or the −y direction). The four first bridge portions 12 may be connected to four sides of the first island portion 11, respectively. Each of the four first bridge portions 12 may be adjacent to each corner of the first island portion 11.

The display apparatus 1 may include second island portions 21 and second bridge portions 22 in the non-display area NDA, for example, the first non-display area NDA1 illustrated in FIG. 4, where the second island portions 21 may be apart from each other in the first direction (for example, the x direction or the −x direction) and the second direction (for example, the y direction or the −y direction), and the second bridge portions 22 may connect the second island portions 21 that are adjacent to each other.

The second bridge portions 22 may be arranged to be spaced apart from each other by a second opening portion CS2 located or defined between the second bridge portions 22. The second bridge portions 22 may have a serpentine shape. In an embodiment, for example, as illustrated in FIG. 4, the second bridge portions 22 may a S-like shape, i.e., approximately have a shape of the letter “S” of the alphabet. A size and/or a width of the second bridge portion 22 may be different from a size and/or a width of the first bridge portion 12. In an embodiment, for example, the size and/or the width of the second bridge portion 22 may be greater than the size and/or the width of the first bridge portion 12. A radius of curvature of a round (or curved) portion of the second bridge portion 22 may be different from a radius of curvature of a round portion of the first bridge portion 12. In an embodiment, for example, the radius of curvature of the round portion of the second bridge portion 22 may be greater than the radius of curvature of the round portion of the first bridge portion 12.

Each second island portion 21 may be connected to the plurality of second bridge portions 22. Each second island portion 21 may be connected to four second bridge portions 22. Two second bridge portions 22 may be arranged at both opposing sides of the second island portion 21 in the first direction (for example, the x direction or the −x direction), and the rest two second bridge portions 22 may be arranged at both opposing sides of the second island portion 21 in the second direction (for example, the y direction or the −y direction). According to an embodiment, four second bridge portions 22 may be connected to four sides of the second island portion 21, respectively. Each second bridge portion 22 may be connected to a central portion of each side of the second island portion 21.

The second island portions 21 in any row arranged in the first non-display area NDA1 may correspond to the first island portions 11 in a plurality of rows arranged in the display area DA. In an embodiment, for example, the second island portions 21 in any row arranged in the first non-display area NDA1 may correspond to the first island portions 11 in an ith row of the display area DA and the first island portions 11 in an (i+1)th row of the display area DA (here, i may be a positive number that is greater than 0). According to another embodiment, the second island portions 21 in any row may correspond to the first island portions 11 in n rows (here, n may be a positive number that is equal to or greater than 3).

The non-display area NDA, for example, the first non-display area NDA1, may include a first sub-non-display area SNDA1 in which the second island portions 21 and the second bridge portions 22 described above are arranged and a second sub-non-display area SNDA2 arranged between the first sub-non-display area SNDA1 and the display area DA. Third bridge portions 23 for connecting the display area DA with the first sub-non-display area SNDA1 may be arranged in the second sub-non-display area SNDA2. An end of the third bridge portion 23 may be connected to the second island portion 21, and the other end of the third bridge portion 23 may be connected to the first island portion 11. In an embodiment, for example, an end of the third bridge portion 23 may be connected to a central portion of a side of the second island portion 21, and the other end of the third bridge portion 23 may be connected to a central portion of a side of the first island portion 11.

The third bridge portions 23 may have a serpentine shape. According to an embodiment, the shape of the third bridge portions 23 may be different from the shape of each of the first bridge portions 12 and the second bridge portions 22. A width of the third bridge portion 23 may be different from the width of the first bridge portion 12 and the width of the second bridge portion 22. The width of the third bridge portion 23 may be greater than the width of the first bridge portion 12 and may be less than the width of the second bridge portion 22. A third opening portion CS3 and a fourth opening portion CS4 having different shapes from each other may be alternately arranged or defined in the second direction (for example, the y direction or the −y direction) between the third bridge portions 23.

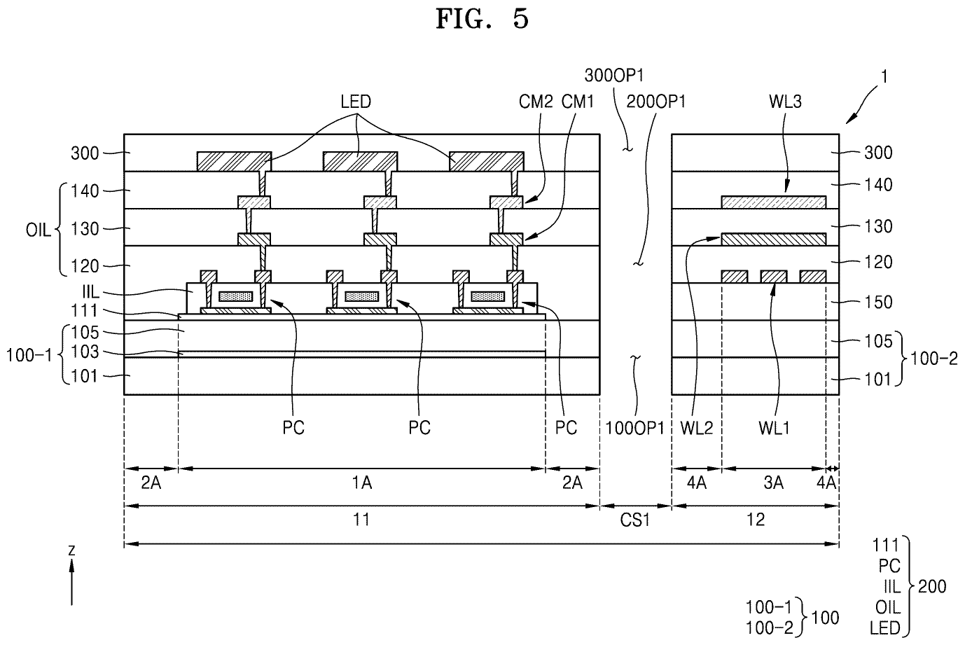

FIG. 5 is a schematic cross-sectional view of the first island portion 11 and the first bridge portion 12 which are arranged in the display area DA of the display apparatus 1 according to an embodiment.

Referring to FIG. 5, the first island portion 11 and the first bridge portion 12 which are arranged in the display area DA may be apart from each other with the first opening portion CS1 therebetween. The first island portion 11 may include the emission elements LED and the circuit electrically connected to the emission elements LED and configured to drive the emission elements LED, for example, a pixel driving circuit portion PC. Also, the first bridge portion 12 may include lines electrically connected to the pixel driving circuit portions PCs respectively arranged in the first island portions 11 that are adjacent to each other.

The display apparatus 1 may include a substrate 100. The substrate 100 may include an island area 100-1 corresponding to the first island portion 11 and a bridge area 100-2 corresponding to the first bridge portion 12.

In the first island portion 11, the first island portion 11 may include a first area 1A and a second area 2A outside the first area 1A. The first area 1A may be defined as an area where a barrier layer 103, a buffer layer 111, an inorganic insulating material layer IIL, and the pixel driving circuit portions PCs are arranged. The first area 1A may be located at the center of the first island portion 11, and a width (or an area) of the first area 1A may be less than a width (or an area) of the first island portion 11. In an embodiment, for example, an edge of the first area 1A may be inwardly distanced or apart from an edge of the first island portion 11. An area from the edge of the first area 1A to the edge of the first island portion 11 may be defined as the second area 2A. The barrier layer 103, the buffer layer 111, the inorganic insulating material layer IIL, and the pixel driving circuit portions PCs may not overlap the second area 2A.

The island area 100-1 of the substrate 100 may include a first base layer 101, the barrier layer 103, and a second base layer 105. In a plan view (or when viewed in a z direction), the edge of the first island portion 11 may correspond to an edge of the island area 100-1.

Each of the first base layer 101 and the second base layer 105 may include at least one selected from polymer resins, such as polyether sulfone, polyarylate, polyether imide, polyethylene naphthalate, polyethylene terephthalate, polyphenylene sulfide, polyimide, polycarbonate, cellulose triacetate, and cellulose acetate propionate. The substrate 100 including at least one selected from the polymer resins may be flexible, rollable, or bendable.

The barrier layer 103 may be disposed between the first base layer 101 and the second base layer 105. The barrier layer 103 may include an inorganic insulating material, such as silicon oxide, silicon nitride, silicon oxynitride, aluminum oxide, titanium oxide, etc. The barrier layer 103 may be arranged in the first area 1A. The barrier layer 103 may not overlap the second area 2A.

The buffer layer 111 including an inorganic insulating material may be disposed on an upper surface (a surface in the z direction) of the island area 100-1, and the pixel driving circuit portions PCs may be disposed on the buffer layer 111. The inorganic insulating material layer IIL and an organic insulating material layer OIL may be disposed between the pixel driving circuit portion PC and the emission element LED. The inorganic insulating material layer IIL may include an inorganic insulating material, such as silicon oxide, silicon nitride, silicon oxynitride, aluminum oxide, titanium oxide, etc. The organic insulating material layer OIL may include a first organic insulating layer 120, a second organic insulating layer 130, and a third organic insulating layer 140. Each of the first organic insulating layer 120, the second organic insulating layer 130, and the third organic insulating layer 140 may include an organic insulating material such as polyimide.

The emission element LED may be disposed on the organic insulating material layer OIL and may be electrically connected to the pixel driving circuit portion PC corresponding to the emission element LED, through a first connection electrode CM1 and a second connection electrode CM2. The first connection electrodes CM1 may be disposed between the first organic insulating layer 120 and the second organic insulating layer 130, and the second connection electrodes CM2 may be disposed between the second organic insulating layer 130 and the third organic insulating layer 140.

The emission elements LEDs may emit light of different colors from each other or light of a same color as each other. According to an embodiment, each of the emission elements LEDs may emit red, green, or blue light. According to some embodiments, the emission elements LEDs may emit white light. According to another embodiment, each of the emission elements LEDs may emit red, green, blue, or white light.

According to an embodiment, as shown in FIG. 5, three pixel driving circuit portions PCs are arranged in each first island portion 11, where three emission elements LEDs are connected to the three pixel driving circuits PCs, respectively. However, the disclosure is not limited thereto. According to another embodiment, the numbers of pixel driving circuit portions PCs and emission elements LEDs arranged in the first island portion 11 may be one, two, or four or more.

An encapsulation layer 300 may be disposed on the emission element LED and may protect the emission element LED from an external force and/or moisture permeability. The encapsulation layer 300 may include an inorganic encapsulation layer and/or an organic encapsulation layer. According to some embodiments, the encapsulation layer 300 may include a structure in which an inorganic encapsulation layer including an inorganic insulating material, an organic encapsulation layer including an organic insulating material, and an inorganic encapsulation layer including an inorganic insulating material are stacked. According to another embodiment, the encapsulation layer 300 may include an organic material such as resins. According to some embodiments, the encapsulation layer 300 may include urethane epoxy acrylate. The encapsulation layer 300 may include a photosensitive material, for example, a material such as a photoresist.

In the first bridge portion 12, the first bridge portion 12 may include a third area 3A and a fourth area 4A outside the third area 3A. The third area 3A may be defined as an area where a first line portion WL1, a second line portion WL2, and a third line portion WL3 are arranged. A width (or an area) of the third area 3A may be less than a width (or an area) of the first bridge portion 12. In an embodiment, for example, an edge of the third area 3A may be inwardly distanced or apart from an edge of the first bridge portion 12. An area from the edge of the third area 3A to the edge of the first bridge portion 12 may be defined as the fourth area 4A. The first line portion WL1, the second line portion WL2, and the third line portion WL3 may not overlap the fourth area 4A.

The bridge area 100-2 of the substrate 100 may include the first base layer 101 and the second base layer 105. In a plan view (or when viewed in the z direction), the edge of the first bridge portion 12 may correspond to an edge of the bridge area 100-2. The first base layer 101 of the bridge area 100-2 may be formed together with the first base layer 101 of the island area 100-1 by a same process as the first base layer 101 of the island area 100-1. The second base layer 105 of the bridge area 100-2 may be formed together with the second base layer 105 of the island area 100-1 by a same process as the second base layer 105 of the island area 100-1.

The bridge area 100-2 of the substrate 100 may not include the barrier layer 103. When the display apparatus 1 is stretched, the bridge area 100-2, which is relatively more transformed than the island area 100-1, may not include a layer including an inorganic insulating material, in which cracks may easily occur, unlike the island area 100-1.

A fourth organic insulating layer 150 may be disposed on an upper surface (a surface in the z direction) of the bridge area 100-2. The fourth organic insulating layer 150 may include an organic insulating material, such as polyimide. An upper surface of the fourth organic insulating layer 150 may be located at approximately a same level as an upper surface of the inorganic insulating material layer IIL. In other words, a height from a lower surface of the first base layer 101 to the upper surface of the fourth organic insulating layer 150 may be approximately the same as a height from the lower surface of the first base layer 101 to the upper surface of the inorganic insulating material layer IIL. The fourth organic insulating layer 150 may reduce a step difference, in the z direction, between lines extending from the first island portion 11 to the first bridge portion 12.

The first organic insulating layer 120, the second organic insulating layer 130, and the third organic insulating layer 140 may be sequentially stacked on the fourth organic insulating layer 150. The first organic insulating layer 120, the second organic insulating layer 130, and the third organic insulating layer 140 of the first bridge portion 12 may be formed together with the layers of the first island portion 11, the layers respectively corresponding thereto, by a same process as the layers of the first island portion 11, the layers respectively corresponding thereto.

The first line portion WL1 may be disposed between the fourth organic insulating layer 150 and the first organic insulating layer 120, the second line portion WL2 may be disposed between the first organic insulating layer 120 and the second organic insulating layer 130, and the third line portion WL3 may be disposed between the second organic insulating layer 130 and the third organic insulating layer 140.

Each of the first line portion WL1, the second line portion WL2, and the third line portion WL3 may include a low resistance-metal material. Each of the first line portion WL1, the second line portion WL2, and the third line portion WL3 may include a conductive material including Mo, Al, Cu, Ti, or the like and may include layers or a single layer including at least one selected from the materials described above.

Each of the first line portion WL1, the second line portion WL2, and the third line portion WL3 may include at least one line extending from the first island portion 11 to the first bridge portion 12. FIG. 5 illustrates an embodiment where the first line portion WL1 may include three lines and each of the second line portion WL2 and the third line portion WL3 may include one line. However, the disclosure is not limited thereto. The number, the thickness, etc. of lines included in each of the first line portion WL1, the second line portion WL2, and the third line portion WL3 may be variously designed as desired. The lines included in the first line portion WL1, the second line portion WL2, and the third line portion WL3 may be signal lines (for example, a gate line, a data line, and the like) configured to provide an electrical signal to transistors included in the pixel driving circuit portion PC of the first island portion 11 or voltage lines (for example, a driving voltage line, an initialization voltage line, and the like) configured to provide a voltage to the transistors included in the pixel driving circuit portion PC of the first island portion 11.

The encapsulation layer 300 may also be arranged in the first bridge portion 12. According to another embodiment, the encapsulation layer 300 may not be arranged in the first bridge portion 12.

Referring to FIGS. 4 and 5, the substrate 100 corresponding to the first island portion 11 and the substrate 100 corresponding to the first bridge portion 12 may be connected to each other. In other words, the plan view illustrated in FIG. 4 above may be substantially the same as a plan view of the substrate 100 of FIG. 5. In other words, the substrate 100 may include the island area 100-1 and the bridge area 100-2, and an opening 100OP1 having a shape that is the same as a shape of the first opening portion CS1 may be defined therebetween.

In an embodiment, the encapsulation layer 300 corresponding to the first island portion 11 and the encapsulation layer 300 corresponding to the first bridge portion 12 may be connected to each other. In an embodiment, for example, the plan view illustrated in FIG. 4 above may be substantially the same as a plan view of the encapsulation layer 300. In other words, the encapsulation layer 300 may include an area corresponding to the first island portion 11 and an area corresponding to the first bridge portion 12, and an opening 300OP1 having a shape that is the same as a shape of the first opening portion CS1 may be defined therebetween.

A circuit-emission element layer 200 between the substrate 100 and the encapsulation layer 300 may include the buffer layer 111, the pixel driving circuit portion PC, the inorganic insulating material layer IIL, the organic insulating material layer OIL, and the emission element LED. Similarly to the substrate 100, the plan view illustrated in FIG. 4 above may be substantially the same as a plan view of the circuit-emission element layer 200. In other words, the circuit-emission element layer 200 may be provided with an opening 200OP1 having a shape that is the same as the shape of the first opening portion CS1.

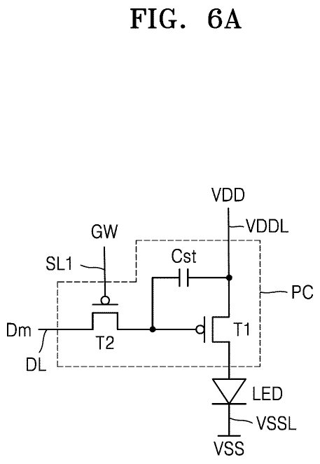

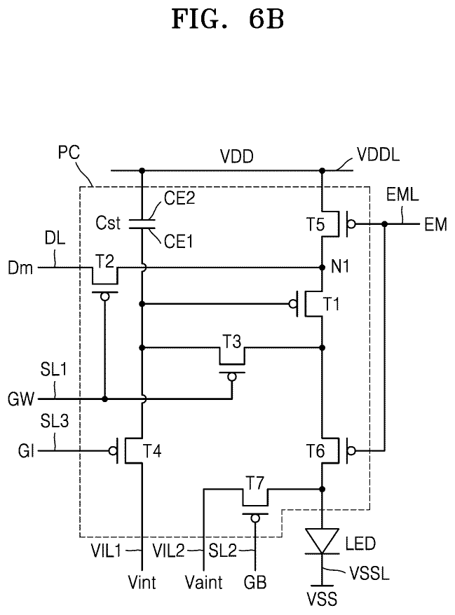

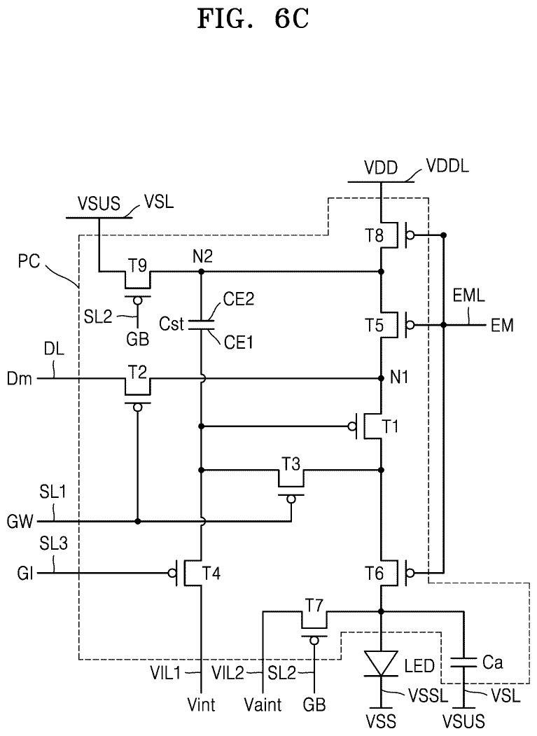

FIGS. 6A to 6C are each an equivalent circuit diagram of a sub-pixel of a display apparatus according to an embodiment.

Referring to FIG. 6A, in an embodiment, an emission element LED corresponding to a sub-pixel may be electrically connected to a pixel driving circuit portion PC, and the pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include a first voltage line VDDL.

The second transistor T2 may be electrically connected to the first scan line SL1 and the data line DL. The first scan line SL1 may be configured to provide a first scan signal GW to a gate electrode of the second transistor T2. The second transistor T2 may be configured to transmit a data signal Dm input from the data line DL to the first transistor T1, in response to the first scan signal GW input from the first scan line SL1.

The storage capacitor Cst may be electrically connected to the second transistor T2 and the first voltage line VDDL and may be configured to store a voltage corresponding to a difference between a voltage transmitted from the second transistor T2 and a first power voltage VDD supplied by the first voltage line VDDL.

The first transistor T1 may be a driving transistor and may be configured to control a driving current flowing through the emission element LED. The first transistor T1 may be connected to the first voltage line VDDL and the storage capacitor Cst. The first transistor T1 may be configured to control a driving current flowing from the first voltage line VDDL to the emission element LED based on a value of the voltage stored in the storage capacitor Cst. The emission element LED may emit light having a certain brightness corresponding to the driving current. A first electrode of the emission element LED may be electrically connected to the first transistor T1, and a second electrode of the emission element LED may be electrically connected to a second voltage line VSSL configured to supply a second power voltage VSS.

FIG. 6A illustrates an embodiment where the pixel driving circuit portion PC may include two transistors and one storage capacitor. However, according to another embodiment, the pixel driving circuit portion PC may include three or more transistors.

Referring to FIG. 6B, in an embodiment, the pixel driving circuit portion PC may include a first transistor T1, a second transistor T2, a third transistor T3, a fourth transistor T4, a fifth transistor T5, a sixth transistor T6, a seventh transistor T7, and a storage capacitor Cst.

The pixel driving circuit portion PC may be electrically connected to signal lines and voltage lines. The signal lines may include a gate line, such as a first scan line SL1, a second scan line SL2, a third scan line SL3 and an emission control line EML, and a data line DL. The voltage lines may include first and second initialization voltage lines VIL1 and VIL2 and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel driving circuit portion PC. The second initialization voltage line VIL2 may be configured to transmit a second initialization voltage Vaint for initializing a first electrode of the emission element LED to the pixel driving circuit portion PC.

The first transistor T1 may be electrically connected to the first voltage line VDDL through the fifth transistor T5 and may be electrically connected to the emission element LED through the sixth transistor T6. The first transistor T1 may function as a driving transistor and may be configured to receive a data signal Dm and transmit a driving current to the emission element LED based on a switching operation of the second transistor T2.

The second transistor T2 may be a data write transistor and may be electrically connected to the first scan line SL1 and the data line DL. The second transistor T2 may be electrically connected to the first voltage line VDDL through the fifth transistor T5. The second transistor T2 may be turned on in response to a first scan signal GW transmitted through the first scan line SL1 and may be configured to perform a switching operation of transmitting the data signal Dm transmitted through the data line DL to a first node N1.

The third transistor T3 may be electrically connected to the first scan line SL1 and may be electrically connected to the emission element LED through the sixth transistor T6. The third transistor T3 may be turned on in response to the first scan signal GW transmitted through the first scan line SL1 and may diode-connect the first transistor T1.

The fourth transistor T4 may be a first initialization transistor and may be electrically connected to the third scan line SL3 and the first initialization voltage line VIL1. The fourth transistor T4 may be turned on in response to a third scan signal GI transmitted through the third scan line SL3 and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel driving circuit portion arranged in a previous row of the corresponding pixel driving circuit portion PC.

The fifth transistor T5 may be an operation control transistor, and the sixth transistor T6 may be an emission control transistor. The fifth transistor T5 and the sixth transistor T6 may be electrically connected to the emission control line EML and may be simultaneously turned on in response to an emission control signal EM transmitted through the emission control line EML to form a current path through which a driving current may flow from the first voltage line VDDL in a direction toward the emission element LED.

The seventh transistor T7 may be a second initialization transistor and may be electrically connected to the second scan line SL2, the second initialization voltage line VIL2, and the sixth transistor T6. The seventh transistor T7 may be turned on in response to a second scan signal GB transmitted through the second scan line SL2 and may be configured to transmit the second initialization voltage Vaint from the second initialization voltage line VIL2 to the first electrode of the emission element LED to initialize the first electrode of the emission element LED.

The storage capacitor Cst may include a first electrode CE1 and a second electrode CE2. The first electrode CE1 may be electrically connected to the gate electrode of the first transistor T1, and the second electrode CE2 may be electrically connected to the first voltage line VDDL. The storage capacitor Cst may be configured to store and sustain a voltage corresponding to a difference between a voltage of the first voltage line VDDL and a voltage of the gate electrode of the first transistor T1, to sustain a voltage applied to the gate electrode of the first transistor T1.

Referring to FIG. 6C, in an embodiment, the pixel driving circuit portion PC may include a first transistor T1, a second transistor T2, a third transistor T3, a fourth transistor T4, a fifth transistor T5, a sixth transistor T6, a seventh transistor T7, an eighth transistor T8, a ninth transistor T9, a storage capacitor Cst, and an auxiliary capacitor Ca.

The pixel driving circuit portion PC may be electrically connected to signal lines and voltage lines. The signal lines may include a gate line, such as a first scan line SL1, a second scan line SL2, a third scan line SL3, a fourth scan line SL4, and an emission control line EML, and a data line DL. The voltage lines may include first and second initialization voltage lines VIL1 and VIL2, a sustaining voltage line VSL, and a first voltage line VDDL.

The first voltage line VDDL may be configured to transmit a first power voltage VDD to the first transistor T1. The first initialization voltage line VIL1 may be configured to transmit a first initialization voltage Vint for initializing the first transistor T1 to the pixel driving circuit portion PC. The second initialization voltage line VIL2 may be configured to transmit a second initialization voltage Vaint for initializing a first electrode of the emission element LED to the pixel driving circuit portion PC. The sustaining voltage line VSL may be configured to provide a sustaining voltage VSUS to a second node N2, for example, a second electrode CE2 of the storage capacitor Cst, in an initialization section (or initialization period) and a data write section (or data write period).

The first transistor T1 may be electrically connected to the first voltage line VDDL through the fifth transistor T5 and the eighth transistor T8 and may be electrically connected to the emission element LED through the sixth transistor T6. The first transistor T1 may function as a driving transistor and may be configured to receive a data signal Dm and transmit a driving current to the emission element LED based on a switching operation of the second transistor T2.

The second transistor T2 may be electrically connected to the first scan line SL1 and the data line DL and may be electrically connected to the first voltage line VDDL through the fifth transistor T5 and the eighth transistor T8. The second transistor T2 may be turned on in response to a first scan signal GW transmitted through the first scan line SL1 and may be configured to perform a switching operation of transmitting the data signal Dm transmitted through the data line DL to a first node N1.

The third transistor T3 may be electrically connected to the first scan line SL1 and may be electrically connected to the emission element LED through the sixth transistor T6. The third transistor T3 may be turned on in response to the first scan signal GW transmitted through the first scan line SL1 and may be configured to diode-connect the first transistor T1 to compensate for a threshold voltage of the first transistor T1.

The fourth transistor T4 may be electrically connected to the third scan line SL3 and the first initialization voltage line VIL1 and may be turned on in response to a third scan signal GI transmitted through the third scan line SL3 and may be configured to transmit the first initialization voltage Vint from the first initialization voltage line VIL1 to a gate electrode of the first transistor T1 to initialize a voltage of the gate electrode of the first transistor T1. The third scan signal GI may correspond to a first scan signal of a different pixel driving circuit portion arranged in a previous row of the corresponding pixel driving circuit portion PC.

The fifth transistor T5, the sixth transistor T6, and the eighth transistor T8 may be electrically connected to the emission control line EML and may be simultaneously turned on in response to an emission control signal EM transmitted through the emission control line EML to form a current path through which a driving current may flow from the first voltage line VDDL in a direction toward the emission element LED.

The seventh transistor T7 may be a second initialization transistor and may be electrically connected to the second scan line SL2, the second initialization voltage line VIL2, and the sixth transistor T6. The seventh transistor T7 may be turned on in response to a second scan signal GB transmitted through the second scan line SL2 and may be configured to transmit the second initialization voltage Vaint from the second initialization voltage line VIL2 to the first electrode of the emission element LED to initialize the first electrode of the emission element LED.

The ninth transistor T9 may be electrically connected to the second scan line SL2, the second electrode CE2 of the storage capacitor Cst, and the sustaining voltage line VSL. The ninth transistor T9 may be turned on in response to the second scan signal GB transmitted through the second scan line SL2 and may be configured to transmit the sustaining voltage VSUS to a second node N2, for example, the second electrode CE2 of the storage capacitor Cst, in an initialization section and a data write section.

Each of the eighth transistor T8 and the ninth transistor T9 may be electrically connected to the second node N2, for example, the second electrode CE2 of the storage capacitor Cst. According to some embodiments, in the initialization section and the data write section, the eighth transistor T8 may be turned off and the ninth transistor T9 may be turned on, and in an emission section (or emission period), the eighth transistor T8 may be turned on and the ninth transistor T9 may be turned off. The sustaining voltage VSUS may be transmitted to the second node N2 in the initialization section and the data write section, and thus, the uniformity of the brightness (for example, the long range uniformity (LRU)) of the display apparatus, which may be impaired due to a voltage drop of the first voltage line VDDL, may be improved.

The storage capacitor Cst may include a first electrode CE1 and the second electrode CE2. The first electrode CE1 may be electrically connected to the gate electrode of the first transistor T1, and the second electrode CE2 may be electrically connected to the eighth transistor T8 and the ninth transistor T9.

The auxiliary capacitor Ca may be electrically connected to the sixth transistor T6, the sustaining voltage line VSL, and the first electrode of the emission element LED. The auxiliary capacitor Ca may be configured to store and sustain a voltage corresponding to a difference between voltages of the first electrode of the emission element LED and the sustaining voltage line VSL, while the seventh transistor T7 and the ninth transistor T9 are being turned on, and thus, the auxiliary capacitor Ca may effectively prevent an increase in black brightness when the sixth transistor T6 is turned off.

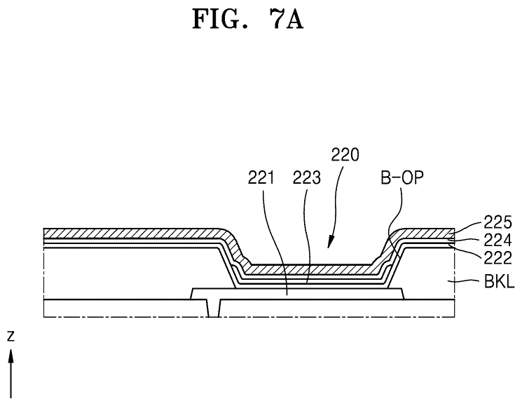

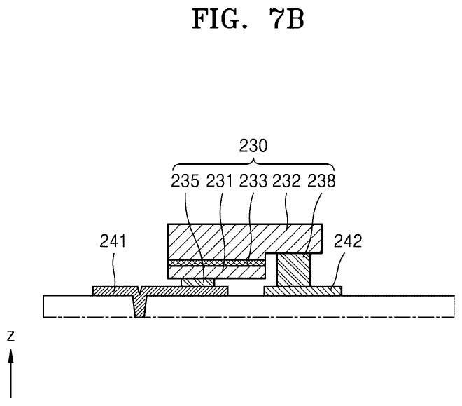

FIGS. 7A and 7B are each a schematic cross-sectional view of an emission element of a display apparatus according to an embodiment.

Referring to FIG. 7A, the emission element according to an embodiment may include an organic light-emitting diode 220 including an organic material. The organic light-emitting diode 220 may include a first electrode 221 disposed on an insulating layer, a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

An edge of the first electrode 221 may be covered by a bank layer BKL including an insulating material. The bank layer BKL may define an opening B-OP overlapping a central portion of the first electrode 221.

The first electrode 221 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). According to another embodiment, the first electrode 221 may include a reflective layer including Ag, Mg, Al, Pt, Pd, Au, Ni, Nd, Ir, Cr, or a compound thereof. According to another embodiment, the first electrode 221 may further include a layer including ITO, IZO, ZnO, AZO or In₂O₃ above/below the reflective layer described above.

The emission layer 223 may include a high molecular-weight or a low molecular-weight organic material emitting light of a certain color. The first functional layer 222 may include a hole transport layer (HTL) and/or a hole injection layer (HIL). The second functional layer 224 may include an electron transport layer (ETL) and/or an electron injection layer (EIL).

The second electrode 225 may include a conductive material having a low work function. In an embodiment, for example, the second electrode 225 may include a (semi) transparent layer including Ag, Mg, Al, Pt, Pd, Au, Ni, Nd, Ir, Cr, Li, Ca, or an alloy thereof. Alternatively, the second electrode 225 may further include a layer, such as ITO, IZO, ZnO, AZO, or In₂O₃, on the (semi) transparent layer including the material described above.

FIG. 7B is a schematic cross-sectional view of an emission element of a display apparatus according to an embodiment.

Referring to FIG. 7B, the emission element according to an embodiment may include an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be electrically connected to a first electrode pad 241 and a second electrode pad 242, respectively, which are arranged in (or directly on) a same layers as the first electrode 235 and the second electrode 238, respectively.

According to some embodiments, the first semiconductor layer 231 may include a p-type semiconductor layer. The p-type semiconductor layer may include a semiconductor material having a composition of InₓAl_{y}Ga_{1-x-y}N (0≤x≤1, 0≤y≤1, 0≤x+y≤1), for example, a material selected from GaN, AlN, AlGaN, InGaN, InN, InAlGaN, AlInV, and the like and may be doped with a p-type dopant, such as Mg, Zn, Ca, Sr, Ba, or the like.

The second semiconductor layer 232 may include, for example, an n-type semiconductor layer. The n-type semiconductor layer may include a semiconductor material having a composition of InₓAl_{y}Ga_{1-x-y}N (0≤x≤1, 0≤y≤1, 0≤x+y≤1), for example, a material selected from GaN, AlN, AlGaN, InGaN, InN, InAlGaN, AlInV, and the like and may be doped with an n-type dopant, such as Si, Ge, Sn, or the like.

The intermediate layer 233 may be a layer where electrons and holes are reunited, and when the electrons and the holes are reunited, transition to a reduced energy level may be performed to generate light having a wavelength corresponding to the reduced energy level. The intermediate layer 233 may include a semiconductor material having a composition of InₓAl_{y}Ga_{1-x-y}N (0≤x≤1, 0≤y≤1, 0≤x+y≤1) and may be formed as a single quantum well structure or a multi-quantum well (MQW) structure. Also, the intermediate layer 233 may also include a quantum wire structure or a quantum dot structure.

In an embodiment, as described with reference to FIG. 7B, the first semiconductor layer 231 may include the p-type semiconductor layer and the second semiconductor layer 232 may include the n-type semiconductor layer. However, the disclosure is not limited thereto. According to another embodiment, the first semiconductor layer 231 may include the n-type semiconductor layer, and the second semiconductor layer 232 may include the p-type semiconductor layer.

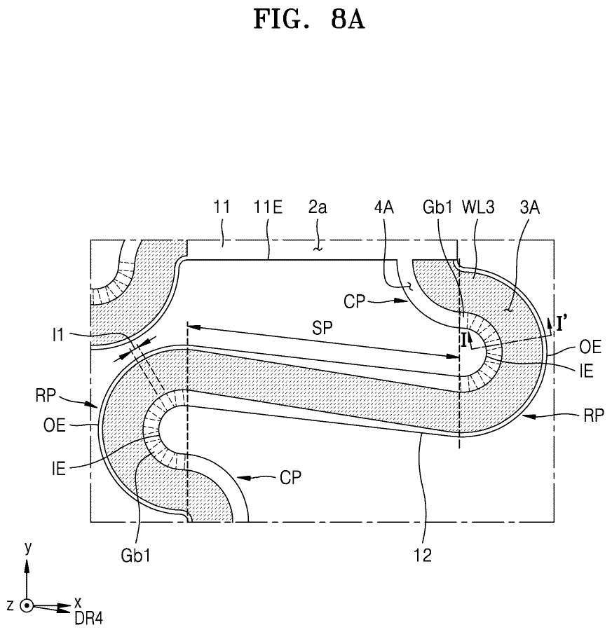

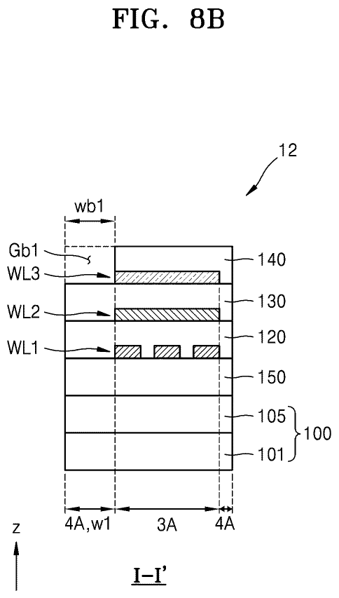

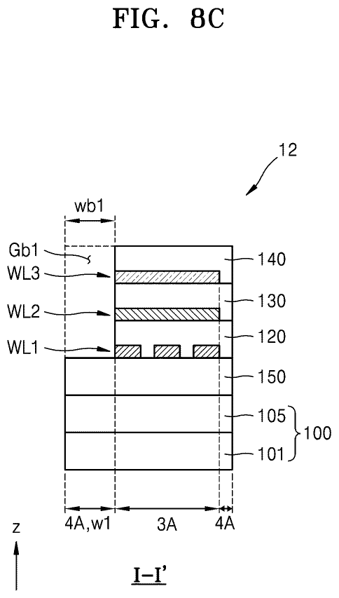

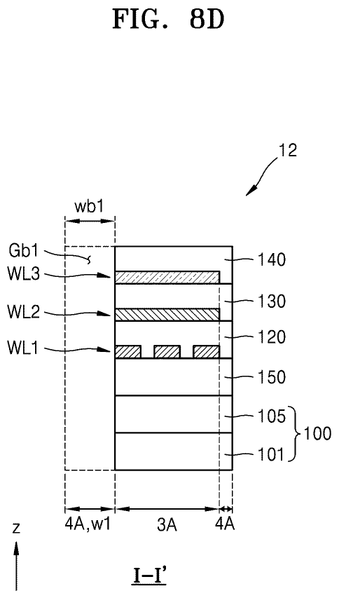

FIG. 8A is a schematic plan view of one first bridge portion 12 and an area adjacent to the first bridge portion 12 which are included in a display apparatus according to an embodiment. Also, FIGS. 8B to 8D are each a schematic cross-sectional view of the first bridge portion 12 according to an embodiment.

Referring to FIGS. 8A and 8B, in an embodiment, the first bridge portion 12 may have a serpentine shape (for example, an approximate shape of the letter “S”). The first bridge portion 12 may be arranged at a gap (or space) between two adjacent first island portions 11.

The first bridge portion 12 may include two round (or curved) portions RPs, a straight-line portion SP, and connection portions CPs. The straight-line portion SP may be arranged between the round portions RPs. The connection portion CP may be arranged between each round portion RP and the first island portion 11. Widths of the round portions RPs, a width of the straight-line portion SP, and widths of the connection portions CPs may be substantially the same as one another.

The round portions RPs may approximately have an arc-type shape, and each round portion RP may be connected to an edge of the first island portion 11. The straight-line portion SP may have an approximate straight-type shape extending in a fourth direction DR4 oblique to a first direction (for example, an x direction or a −x direction) and a second direction (for example, a y direction or a −y direction).

Each round portion RP may have an inner edge IE and an outer edge OE. The inner edge IE may extend along an arc of an imaginary circle having a first radius. The outer edge OE may extend along an arc of an imaginary circle having a second radius which is greater than the first radius. An end of the inner edge IE may be connected to an edge of the connection portion CP, and the other (or an opposing) end of the inner edge IE may be connected to an edge of the straight-line portion SP. An end of the outer edge OE may be connected to an edge of the first island portion 11, and the other end of the outer edge OE may be connected to the other edge of the straight-line portion SP.

In an embodiment, the first bridge portion 12 may include the fourth organic insulating layer 150, the first organic insulating layer 120, the second organic insulating layer 130, and the third organic insulating layer 140 sequentially stacked on the substrate 100 corresponding to the first bridge portion 12. The first line portion WL1 may include at least one line disposed between the fourth organic insulating layer 150 and the first organic insulating layer 120, the second line portion WL2 may include at least one line disposed between the first organic insulating layer 120 and the second organic insulating layer 130, and the third line portion WL3 may include at least one line disposed between the second organic insulating layer 130 and the third organic insulating layer 140.

FIGS. 8A to 8D illustrate embodiments where the first line portion WL1 may include three lines and each of the second line portion WL2 and the third line portion WL3 may include one line. However, the disclosure is not limited thereto. The number of lines included in each line portion may be variously changed. Also, lines included in the first bridge portions 12 connecting the first island portions 11 adjacent to each other in a first direction (for example, an x direction or a −x direction) from among the first bridge portions 12 and lines included in the first bridge portions 12 connecting the first island portions 11 adjacent to each other in a second direction (for example, a y direction or a −y direction) from among the first bridge portions 12 may have different structures from each other.

The third area 3A may be defined as an area where the first line portion WL1, the second line portion WL2, and the third line portion WL3 are arranged, and the fourth areas 4A may be defined as areas between the third area 3A and both opposing side edges of the first bridge portion 12. In an embodiment, for example, two fourth areas 4A may be arranged with the third area 3A therebetween.

A width (or an area) of the third area 3A may be less than a width (or an area) of the first bridge portion 12. The third area 3A may be arranged to be adjacent to the outer edge OE of each round portion RP relatively more than the inner edge IE of each round portion RP. In an embodiment, for example, the third area 3A may be apart from the inner edge IE by a first distance and may be apart from the outer edge OE by a second distance, in a direction perpendicular to an extension direction of the first bridge portion 12. Here, the first distance may be greater than the second distance.

When the first bridge portion 12 is shrunk or stretched by an external force, the inner edge IE of each of round portion RP may receive greater stress than the outer edge OE of each round portion RP. Thus, according to embodiments, the third area 3A may be arranged to be relatively closer to the outer edge OE of each round portion RP than to the inner edge IE of each round portion RP, and thus, the occurrence of cracks in the lines may be substantially reduced or effectively prevented.

In the fourth area 4A of the first bridge portion 12, first groove patterns Gb1 that are open in a direction toward an upper surface (a surface in a +z direction) of the first bridge portion 12 may be arranged or defined along the inner edge IE of each round portion RP. In a plan view (for example, when viewed in a direction perpendicular to the substrate, i.e., the z direction), each of the first groove patterns Gb1 may have a square shape having an open side, with a side of the first groove pattern Gb1 being in contact with the inner edge IE of each round portion RP. According to other embodiments, the first groove patterns Gb1 may have various shapes, such as polygonal shapes, semicircular shapes, amorphous shapes, etc.

The first groove patterns Gb1 may be defined by at least one insulating layer. The insulating layer may include an organic insulating material or an inorganic insulating material. In an embodiment, for example, the first bridge portion 12 may include the substrate 100, and the fourth organic insulating layer 150, the first organic insulating layer 120, the second organic insulating layer 130, and the third organic insulating layer 140 sequentially stacked on the substrate 100. The first groove patterns Gb1 may be defined by one or more from among the fourth organic insulating layer 150, the first organic insulating layer 120, the second organic insulating layer 130, and the third organic insulating layer 140. In an embodiment where an inorganic insulating layer is arranged in the first bridge portion 12, the first groove patterns Gb1 may be defined by the inorganic insulating layer.

According to an embodiment, as illustrated in FIG. 8B, the first groove patterns Gb1 may be defined by the third organic insulating layer 140. In an embodiment, for example, the first groove patterns Gb1 may be openings (or grooves) defined by removing a portion of the third organic insulating layer 140.

According to another embodiment, the first groove patterns Gb1 may be defined by openings defined in the third organic insulating layer 140 and openings (or grooves) defined in organic insulating layers below the third organic insulating layer 140, where the openings (or grooves) overlapping each other. In other words, the first groove patterns Gb1 may be defined by the plurality of organic insulating layers. In an embodiment, for example, as illustrated in FIG. 8C, the first groove patterns Gb1 may be formed by the openings defined in the third organic insulating layer 140, the openings defined in the second organic insulating layer 130, and the openings (or the grooves) defined in the first organic insulating layer 120, where the openings (or the grooves) overlap one another. Alternatively, the first groove patterns Gb1 may be formed by the openings defined in the third organic insulating layer 140 and the openings (or the grooves) defined in the second organic insulating layer 130, where the openings (or the grooves) overlap each other. Alternatively, the first groove patterns Gb1 may be formed by the openings defined in the third organic insulating layer 140, the openings defined in the second organic insulating layer 130, the openings defined in the first organic insulating layer 120, and the openings (or the grooves) defined in the fourth organic insulating layer 150, where the openings (or the grooves) overlap one another.

According to another embodiment, the first groove pattern Gb1 may be defined by the plurality of organic insulating layers and the substrate 100. In an embodiment, for example, as illustrated in FIG. 8D, the first groove patterns Gb1 may extend from an upper surface of the second organic insulating layer 130 to a lower surface of the first base layer 101 and may be defined through the first bridge portion 12.

The first groove pattern Gb1 may have a first length l1 in the extension direction of the first bridge portion 12. Here, the extension direction of the first bridge portion 12 may denote a direction toward a central line (or an extending direction) of the first bridge portion 12. According to an embodiment, the first length l1 may be in a range from about 3 micrometers (μm) to about 3.5 μm.

The first groove pattern Gb1 may have a first pattern width wb1 in a direction perpendicular to the extension direction of the first bridge portion 12. In an embodiment where the fourth area 4A corresponding to the first groove pattern Gb1 has a first width w1 in the direction perpendicular to the extension direction of the first bridge portion 12, the first pattern width wb1 may be less than or substantially the same as the first width w1. Thus, the first groove pattern Gb1 may be arranged in the fourth area 4A and may not overlap the third area 3A.

In a plan view, an inner edge of an upper surface of the round portion RP may have a concavo-convex portion having a zigzag shape. When the first bridge portion 12 is shrunk or stretched, the first groove patterns Gb1 may distribute stress concentrated at the inner edge IE of the first bridge portion 12.

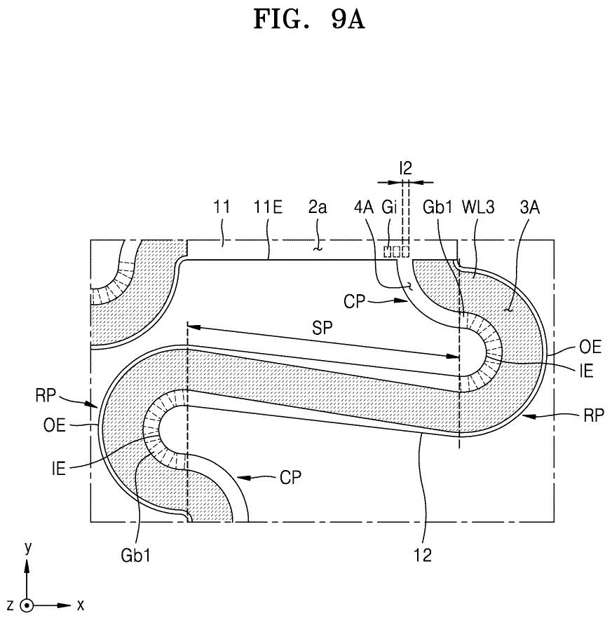

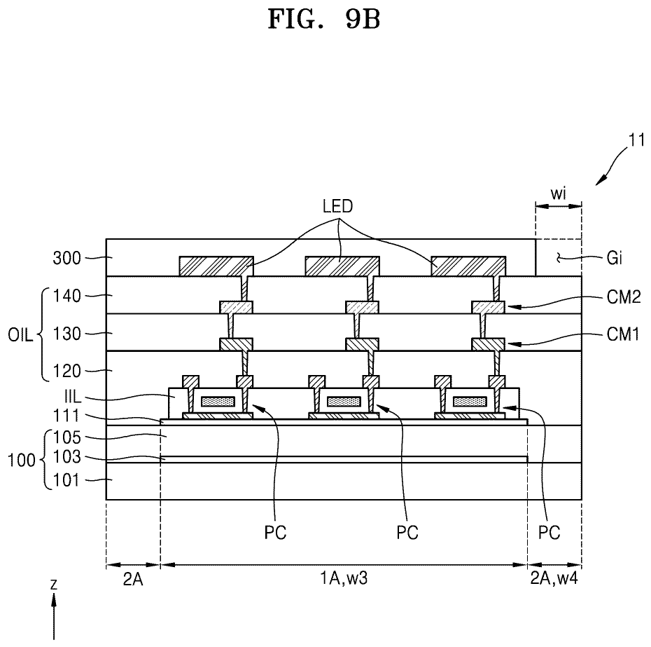

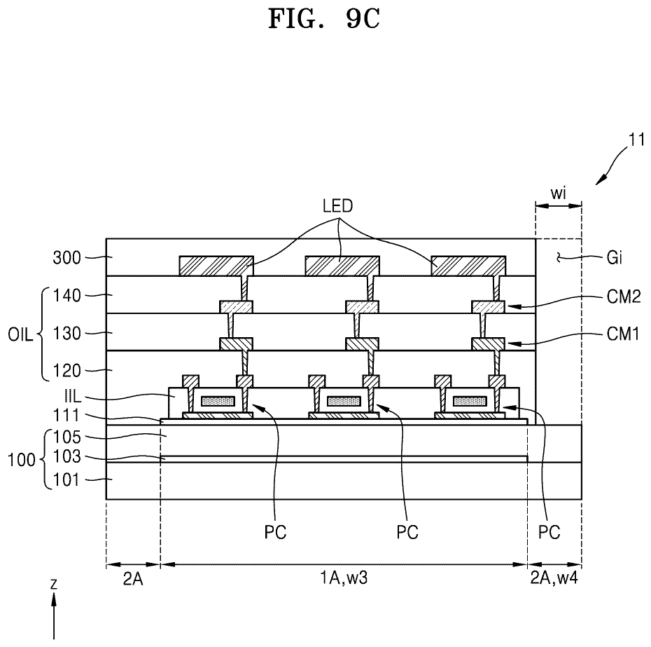

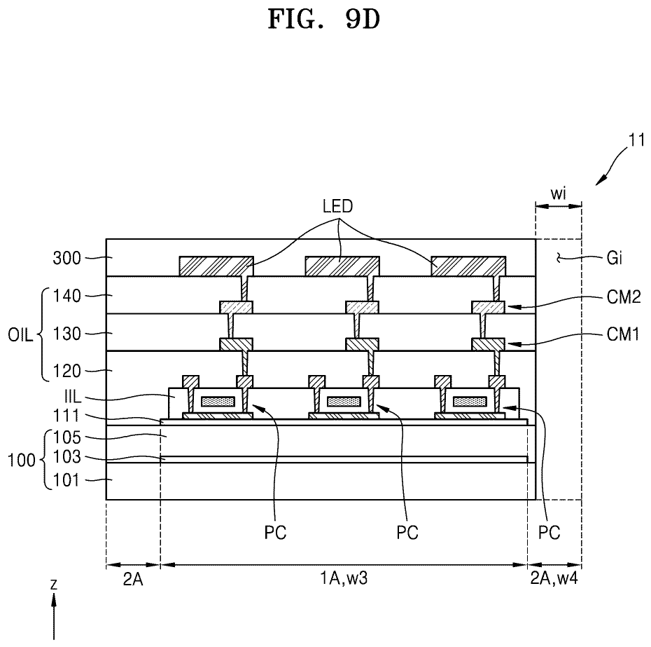

FIG. 9A is a schematic plan view of one first bridge portion 12 and an area adjacent to the first bridge portion 12 which are included in a display apparatus according to an embodiment. Also, FIGS. 9B to 9D are schematic cross-sectional views of the first island portion 11 according to an embodiment.

Referring to FIGS. 9A and 9B, the first bridge portion 12 may include two round portions RPs, two connection portions CPs, and a straight-line portion SP between the round portions RPs. Each of the connection portions CP may be arranged between the round portion RP and the first island portion 11.

Each of the two round portions RPs may have an inner edge IE and an outer edge OE. The inner edge IE may extend along an arc of an imaginary circle having a first radius. The outer edge OE may extend along an arc of an imaginary circle having a second radius which is greater than the first radius.

The first bridge portion 12 may include a third area 3A and fourth areas 4A arranged at both opposing sides of the third area 3A. The third area 3A may be defined as an area where the first line portion WL1, the second line portion WL2, and the third line portion WL3 are arranged, and the fourth areas 4A may be defined as areas between the third area 3A and both opposing side edges of the first bridge portion 12.

The first island portion 11 may include a first area 1A and a second area 2A arranged outside the first area 1A. The first area 1A may be defined as an area where the barrier layer 103, the buffer layer 111, the inorganic insulating material layer IIL, and circuit portions are arranged. An area from an edge of the first area 1A to an edge of the first island portion 11 may be defined as the second area 2A. In a plan view, the second area 2A may have a frame shape surrounding the first area 1A.

The barrier layer 103, the buffer layer 111, the inorganic insulating material layer IIL, and the pixel driving circuit portions PCs may not overlap the second area 2A. Stress due to the transformation of the first bridge portions 12 may be concentrated at the second area 2A. Thus, unlike the first area 1A, the second area 2A may not include a layer including an inorganic insulating material in which cracks may easily occur. The first area 1A may have a third width w3 which is less than a width of the first island portion 11, and the second area 2A may approximately have a fourth width w4.

In the second area 2A, second groove patterns Gi that are open in a direction toward an upper surface (a surface in a +z direction) of the first island portion 11 may be arranged to be adjacent to the first bridge portion 12. In a plan view, each of the second groove patterns Gi may have a square shape with a side of the second groove pattern Gi being adjacent to the edge of the first island portion 11. According to other embodiments, the second groove patterns Gi may have various shapes, such as polygonal shapes, semicircular shapes, amorphous shapes, etc.

The first island portion 11 may include the substrate 100, the buffer layer 111 disposed on the substrate 100, the inorganic insulating material layer IIL and the pixel driving circuit portions PCs disposed on the buffer layer 111, and the organic insulating material layers OIL and the encapsulation layer 300 disposed on the pixel driving circuit portions PCs.

The second groove patterns Gi may be defined by at least one insulating layer. The insulating layer may include an organic insulating material or an inorganic insulating material. According to an embodiment, as illustrated in FIG. 9B, the second groove patterns Gi may be defined by the encapsulation layer 300. In an embodiment, for example, the second groove patterns Gi may be openings (or grooves) defined by removing a portion of the encapsulation layer 300.

According to another embodiment, the second groove patterns Gi may be defined by the encapsulation layer 300 and the organic insulating material layer OIL. In an embodiment, for example, as illustrated in FIG. 9C, the second groove patterns Gi may be formed by openings defined in the encapsulation layer 300, openings defined in the third organic insulating layer 140, openings defined in the second organic insulating layer 130, openings defined in the first organic insulating layer 120, and openings (or grooves) defined in the fourth organic insulating layer 150, where the openings (or the grooves) overlap one another. Alternatively, the second groove patterns Gi may be formed by the openings defined in the encapsulation layer 300, the openings defined in the third organic insulating layer 140, and the openings (or grooves) defined in the second organic insulating layer 130, the openings (or the grooves) overlapping one another. Alternatively, the second groove patterns Gi may be formed by the openings defined in the encapsulation layer 300 and the openings (or grooves) defined in the third organic insulating layer 140, where the openings (or the grooves) overlap each other.

According to another embodiment, the second groove patterns Gi may be defined by the encapsulation layer 300, the organic insulating material layer OIL, and the substrate 100. In an embodiment, for example, as illustrated in FIG. 9D, the second groove patterns Gi may be formed by the openings defined in the encapsulation layer 300, the openings defined in the organic insulating material layer OIL, and openings (or grooves) defined in the substrate 100, where the openings (or the grooves) overlap one another.

The second groove pattern Gi may have a second length l2 in a direction parallel with the edge of the first island portion 11. In an embodiment, the second length l2 may be in a range from about 1.8 μm to about 2 μm.

The second groove pattern Gi may have a second pattern width wi in a direction perpendicular to the edge of the first island portion 11. When the second area 2A in which the second groove patterns Gi are arranged has a fourth width w4 in the direction perpendicular to the edge of the first island portion 11, the second pattern width wi may be less than or substantially the same as the fourth width w4. Thus, the second groove patterns Gi may be arranged in the second area 2A and may not overlap the first area 1A.

In a plan view, an edge of an upper surface of the first island portion 11 may have a concavo-convex portion having a zigzag shape, in an area adjacent to the first bridge portion 12. When the first bridge portion 12 is transformed, the second groove patterns Gi may distribute stress concentrated at an area in which the first island portion 11 and the first bridge portion 12 are connected with each other.

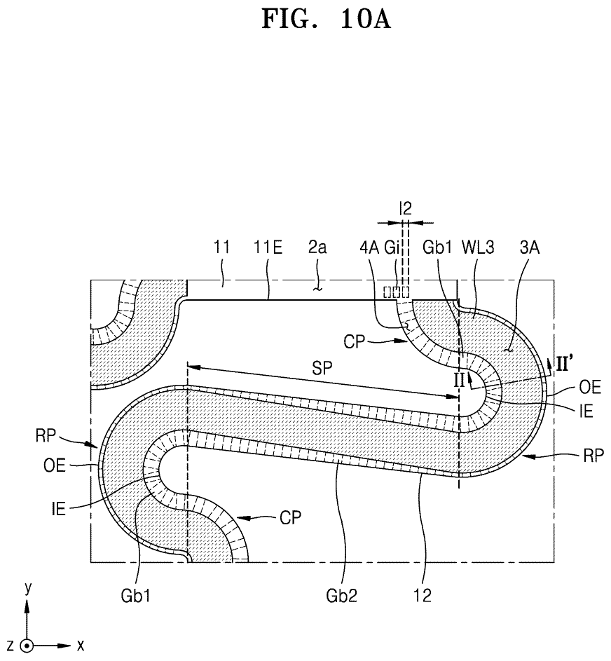

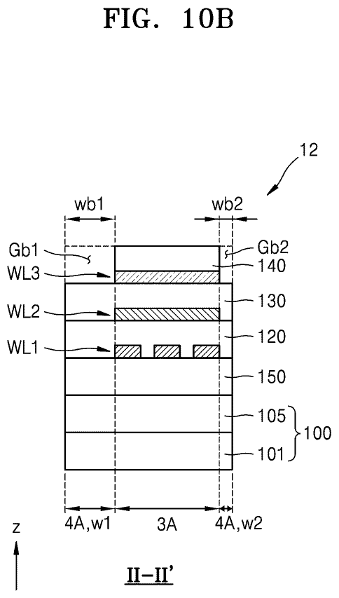

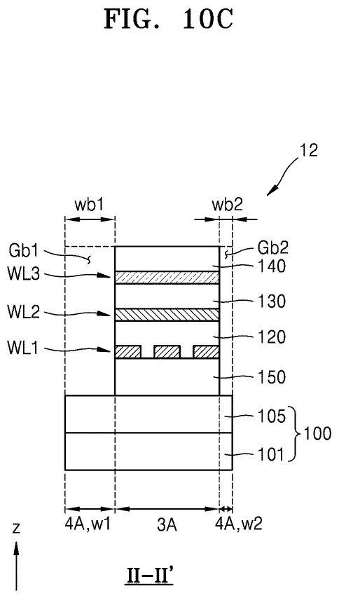

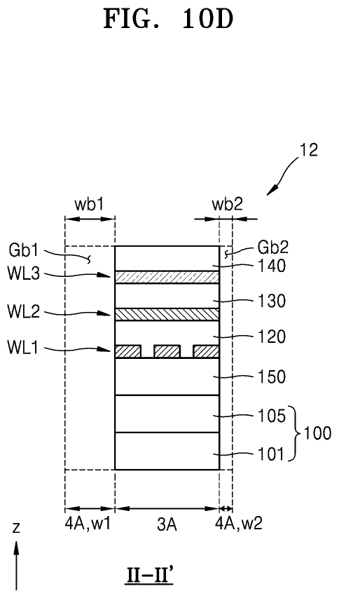

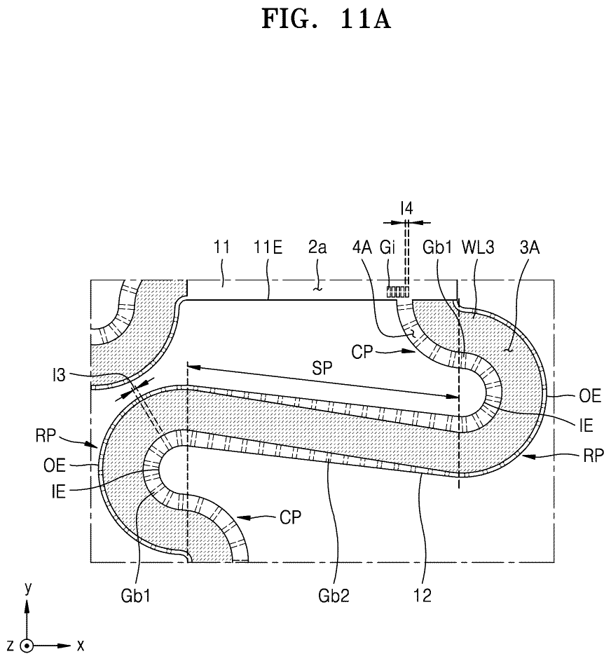

FIG. 10A is a schematic plan view of one first bridge portion 12 and an area adjacent to the first bridge portion 12 which are included in a display apparatus according to an embodiment. Also, FIGS. 10B to 10D are each a schematic cross-sectional view of the first bridge portion 12 according to an embodiment.

Referring to FIGS. 10A and 10B, in an embodiment, the first bridge portion 12 may include two round portions RPs, two connection portions CPs, and a straight-line portion SP between the round portions RPs. Each of the connection portions CP may be arranged between the round portion RP and the first island portion 11.

Each of the two round portions RPs may have an inner edge IE and an outer edge OE. The inner edge IE may extend along an arc of an imaginary circle having a first radius. The outer edge OE may extend along an arc of an imaginary circle having a second radius which is greater than the first radius.

The first bridge portion 12 may include a third area 3A and a fourth area 4A. The third area 3A may be defined as an area where the first line portion WL1, the second line portion WL2, and the third line portion WL3 are arranged, and the fourth areas 4A may be defined as areas between the third area 3A and both opposing side edges of the first bridge portion 12. In an embodiment, for example, two fourth areas 4A may be arranged with the third area 3A therebetween.

In the fourth area 4A of the first bridge portion 12, groove patterns that are open in a direction toward an upper surface of the first bridge portion 12 may be arranged along both opposing side edges of the first bridge portion 12. The groove patterns may include first groove patterns Gb1 arranged along the inner edge IE of each round portion RP and third groove patterns Gb2 arranged along the outer edge OE of each round portion RP, an edge of the connection portion CP, and both opposing side edges of the straight-line portion SP. In a plan view (for example, when viewed in a direction perpendicular to the substrate or the z direction), each of the first groove patterns Gb1 and each of the third groove patterns Gb2 may have square shapes having open sides, with a side of the first groove pattern Gb1 and a side of the third groove pattern Gb2 being in contact with any edges of the first bridge portion 12. According to other embodiments, the first groove patterns Gb1 and the third groove patterns Gb2 may each have various shapes, such as polygonal shapes, semicircular shapes, amorphous shapes, etc.

The third groove patterns Gb2 may be defined by at least one insulating layer. The insulating layer may include an organic insulating material or an inorganic insulating material. The first bridge portion 12 may include the substrate 100, and the fourth organic insulating layer 150, the first organic insulating layer 120, the second organic insulating layer 130, and the third organic insulating layer 140 sequentially stacked on the substrate 100. According to an embodiment, the first groove patterns Gb1 and the third groove patterns Gb2 may be defined by one or more from among the fourth organic insulating layer 150, the first organic insulating layer 120, the second organic insulating layer 130, and the third organic insulating layer 140.

According to an embodiment, as illustrated in FIG. 10B, the first groove patterns Gb1 and the third groove patterns Gb2 may be defined by the third organic insulating layer 140. In an embodiment, for example, the first groove patterns Gb1 and the third groove patterns Gb2 may be openings (or grooves) defined by removing a portion of the third organic insulating layer 140.

According to another embodiment, the first groove patterns Gb1 and the third groove patterns Gb2 may be defined by openings defined in the third organic insulating layer 140 and openings (or grooves) defined in organic insulating layers below the third organic insulating layer 140, where the openings (or the grooves) overlap each other. In other words, the first groove patterns Gb1 and the third groove patterns Gb2 may be defined by the plurality of organic insulating layers. In an embodiment, for example, as illustrated in FIG. 10C, the first groove patterns Gb1 and the third groove patterns Gb2 may be formed by the openings defined in the third organic insulating layer 140, the openings defined in the second organic insulating layer 130, and the openings (or the grooves) defined in the first organic insulating layer 120, where the openings (or the grooves) overlap one another. Alternatively, the first groove patterns Gb1 and the third groove patterns Gb2 may be formed by the openings defined in the third organic insulating layer 140 and the openings (or the grooves) defined in the second organic insulating layer 130, where the openings (or the grooves) overlap each other. Alternatively, the first groove patterns Gb1 and the third groove patterns Gb2 may be formed by the openings defined in the third organic insulating layer 140, the openings defined in the second organic insulating layer 130, the openings defined in the first organic insulating layer 120, and the openings (or the grooves) defined in the fourth organic insulating layer 150, where the openings (or the grooves) overlap one another.

According to another embodiment, the first groove patterns Gb1 and the third groove patterns Gb2 may be defined by the plurality of organic insulating layers and the substrate 100. In an embodiment, for example, as illustrated in FIG. 10D, the first groove patterns Gb1 and the third groove patterns Gb2 may extend from an upper surface of the second organic insulating layer 130 to a lower surface of the first base layer 101 and may be defined through the first bridge portion 12.

The first groove pattern Gb1 may have a first pattern width wb1 in a direction perpendicular to an extension direction of the first bridge portion 12, and the third groove pattern Gb2 may have a third pattern width wb2 in the direction perpendicular to the extension direction of the first bridge portion 12. When the fourth area 4A corresponding to the first groove pattern Gb1 has a first width w1 in the direction perpendicular to the extension direction of the first bridge portion 12, the first pattern width wb1 may be less than or substantially the same as the first width w1. When the fourth area 4A corresponding to the third groove pattern Gb2 has a second width w2 in the direction perpendicular to the extension direction of the first bridge portion 12, the third pattern width wb2 may be less than or substantially the same as the second width w2. Thus, the first groove patterns Gb1 and the third groove patterns Gb2 may be arranged in the fourth area 4A and may not overlap the third area 3A.

In a plan view, an edge of an upper surface of the first bridge portion 12 may have a concavo-convex portion having a zigzag shape. When the first bridge portion 12 is shrunk or stretched, the first groove patterns Gb1 and the third groove patterns Gb2 may distribute stress concentrated at a portion of the first bridge portion 12.

According to an embodiment, in a second area 2A of the first island portion 11, second groove patterns Gi that are open in a direction toward an upper surface of the first island portion 11 may be arranged to be adjacent to the first bridge portion 12. According to other embodiments, the second groove patterns Gi may have various shapes, such as polygonal shapes, semicircular shapes, amorphous shapes, etc. According to another embodiment, the second groove patterns Gi may be omitted.

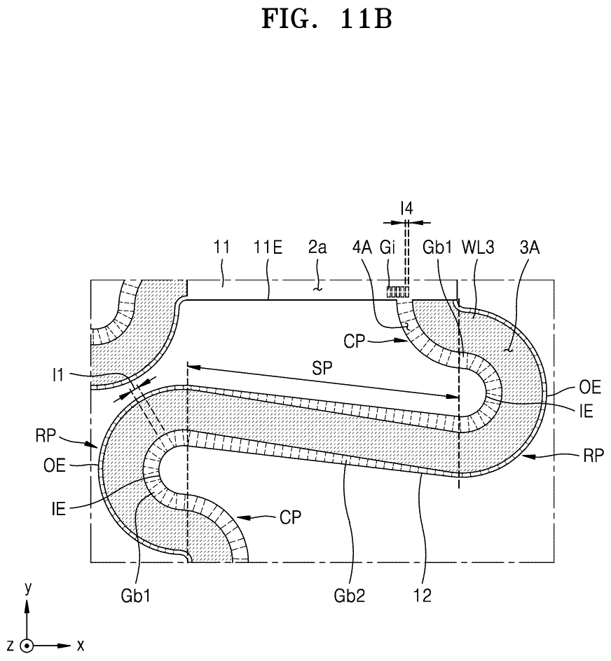

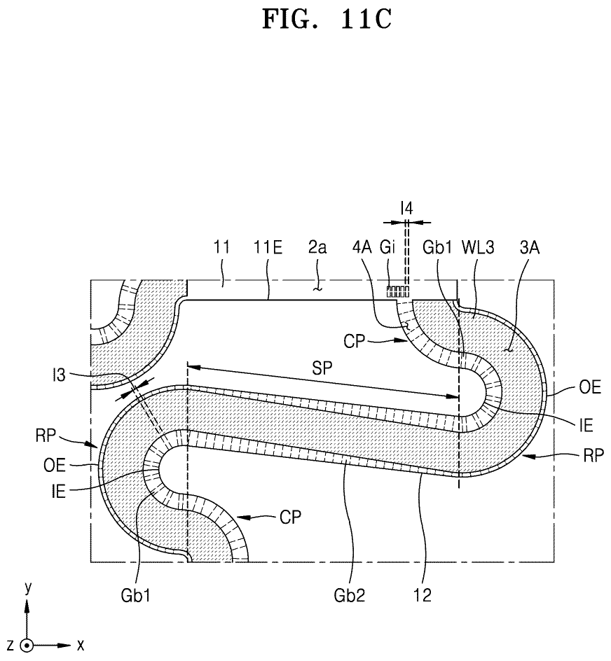

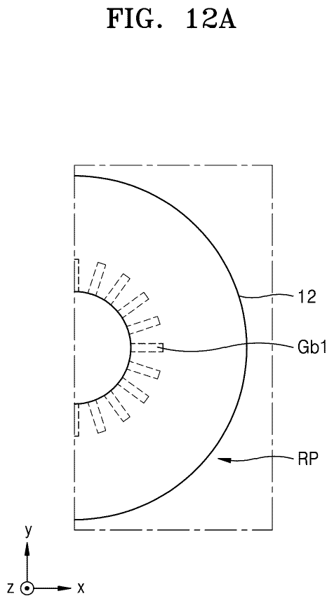

FIGS. 11A to 11C are schematic plan views of one first bridge portion 12 and an area adjacent to the first bridge portion 12 which are included in a display apparatus according to an embodiment.

Referring to FIGS. 11A and 11C, in an embodiment, the first bridge portion 12 may include two round portions RPs, two connection portions CPs, and a straight-line portion SP between the round portions RPs. Each of the connection portions CP may be arranged between the round portion RP and the first island portion 11.

Each of the two round portions RPs may have an inner edge IE and an outer edge OE. The inner edge IE may extend along an arc of an imaginary circle having a first radius. The outer edge OE may extend along an arc of an imaginary circle having a second radius which is greater than the first radius.

The first bridge portion 12 may include a third area 3A and a fourth area 4A. The third area 3A may be defined as an area where the first line portion WL1, the second line portion WL2, and the third line portion WL3 are arranged, and the fourth areas 4A may be defined as areas between the third area 3A and both opposing side edges of the first bridge portion 12. In an embodiment, for example, two fourth areas 4A may be arranged with the third area 3A therebetween.

In the fourth area 4A of the first bridge portion 12, groove patterns that are open in a direction toward an upper surface of the first bridge portion 12 may be arranged along both opposing side edges of the first bridge portion 12. The groove patterns may include first groove patterns Gb1 arranged along the inner edge IE of each round portion RP and third groove patterns Gb2 arranged along the outer edge OE of each round portion RPs, an edge of the connection portion CP, and both opposing side edges of the straight-line portion SP.

According to an embodiment, in a second area 2A of the first island portion 11, second groove patterns Gi that are open in a direction toward an upper surface of the first island portion 11 may be arranged to be adjacent to the first bridge portion 12.

In an embodiment, as shown in FIGS. 11A and 11C, each of the first groove patterns Gb1 and each of the third groove patterns Gb2 may have a first length l1 or a third length l3 which is less than the first length l1, in an extension direction of the first bridge portion 12. The second groove patterns Gi may have a second length l2 or a fourth length l4 which is less than the second length l2 in a direction parallel with an edge of the first island portion 11. According to an embodiment, the first length l1 may be in a range from about 3 μm to about 3.5 μm, and the third length l3 may be in a range from about 1.4 μm to about 1.8 μm. The second length l2 may be from about 1.8 μm to about 2 μm, and the fourth length l4 may be in a range from about 1.3 μm to about 1.7 μm.

According to an embodiment, as illustrated in FIG. 11A, the first groove patterns Gb1 and the third groove patterns Gb2 may have the third length l3, and the second groove patterns Gi may have the fourth length l4. According to an embodiment, as illustrated in FIG. 11B, the first groove patterns Gb1 and the third groove patterns Gb2 may have the first length l1, and the second groove patterns Gi may have the fourth length 14. According to an embodiment, as illustrated in FIG. 11C, the first groove patterns Gb1 may have the third length l3, the third groove patterns Gb2 may have the first length l1, and the second groove patterns Gi may have the fourth length l4. In other embodiments, various combinations may be possible.

By changing or modifying the length of the first groove patterns Gb1, the length of the second groove patterns Gi, and the length of the third groove patterns Gb2, stress applied in each area may be effectively distributed.

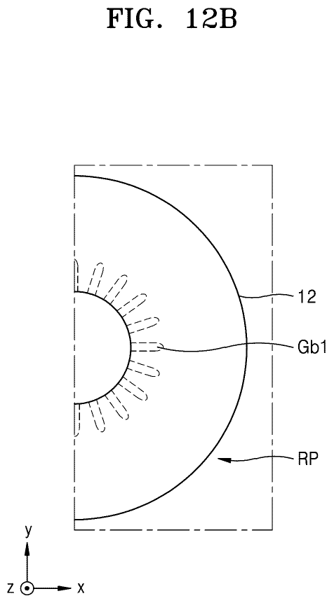

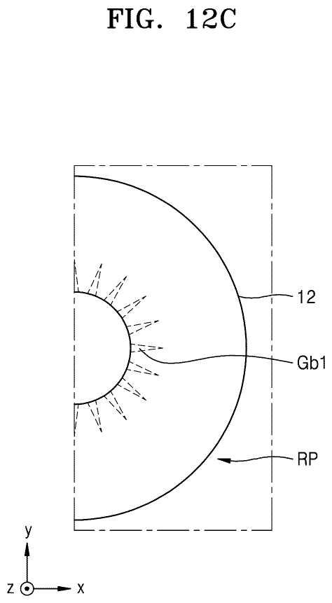

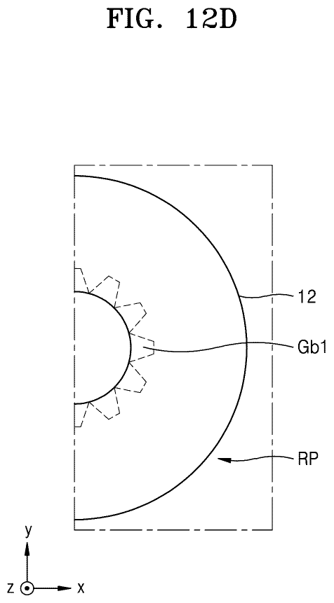

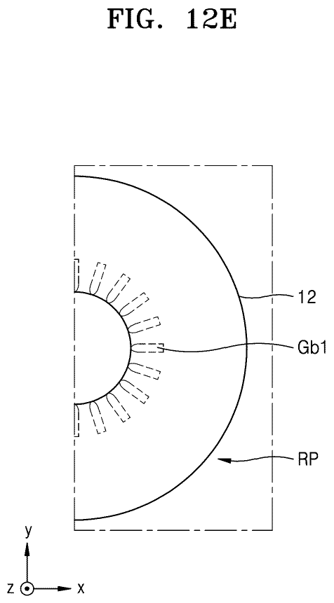

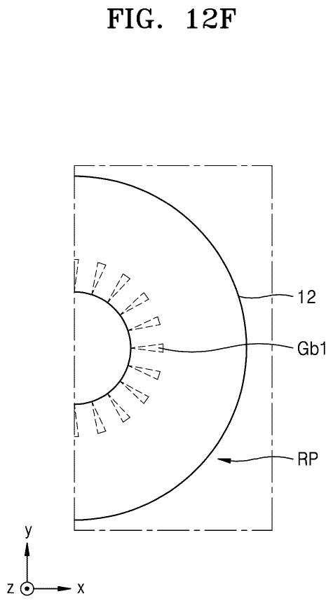

FIGS. 12A to 12F are schematic plan views of a portion of the first bridge portion 12 according to an embodiment.

Referring to FIGS. 12A to 12F, in a plan view, the first groove patterns Gb1 may have various shapes, such as polygonal shapes, semicircular shapes, amorphous shapes, etc. According to an embodiment, as illustrated in FIG. 12A, in a plan view, the first groove pattern Gb1 may have a rectangular shape having an open side, with a side of the first groove pattern Gb1 being in contact with an edge of the first bridge portion 12. The first groove pattern Gb1 may have a constant width in a direction perpendicular to an extension direction of the first bridge portion 12.

FIG. 12B illustrates an embodiment where the first groove patterns Gb1 each has a round edge in a direction toward the center of the first bridge portion 12. The first groove pattern Gb1 may have a segmented oval shape or may have a square shape having a round portion in a direction toward the center of the first bridge portion 12. The first groove pattern Gb1 may have the shape with a round edge, and thus, when the first bridge portion 12 is transformed, the stability may be improved.

FIG. 12C illustrates t an embodiment where he first groove patterns Gb1 each has a triangular shape having one vertex toward the center of the first bridge portion 12 and having an opposite side of the vertex, which is in contact with an edge of the first bridge portion 12. FIG. 12D illustrates an embodiment where the first groove patterns Gb1 each has a ladder shape in which a longer opposite of parallel opposites is in contact with an edge of the first bridge portion 12, and a shorter opposite of the parallel opposites is toward the center of the first bridge portion 12. In an embodiment, as illustrated in FIGS. 12C and 12D, where a width (or a length) of the first groove pattern Gb1 in an extension direction of the first bridge portion 12 increases toward the edge of the first bridge portion 12, the round portion RP may be easily shrunk.

FIG. 12E illustrates an embodiment where the first groove patterns Gb1 each has a round edge in a direction toward an edge of the first bridge portion 12. The first groove pattern Gb1 may have a segmented oval shape or may have a square shape having a round portion in a direction toward the edge of the first bridge portion 12. FIG. 12F illustrates an embodiment where the first groove patterns Gb1 each has a triangular shape having one vertex toward the edge of the first bridge portion 12 and having an opposite side of the vertex toward the center of the first bridge portion 12. In an embodiment, as illustrated in FIGS. 12E and 12F, when a width (or a length) of the first groove pattern Gb1 in an extension direction of the first bridge portion 12 decreases toward the edge of the first bridge portion 12, the round portion RP may be easily stretched.

FIGS. 12A to 12F illustrate only the first groove patterns Gb1, but the shapes of the first groove patterns Gb1 may be applied to the second groove patterns Gi (see FIG. 9A) and/or the third groove patterns Gb2 (see FIG. 10A) in the same or substantially the same fashion.

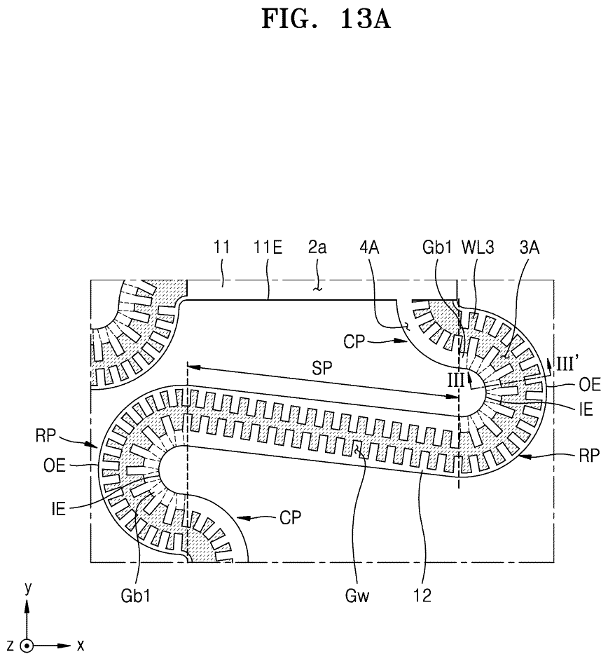

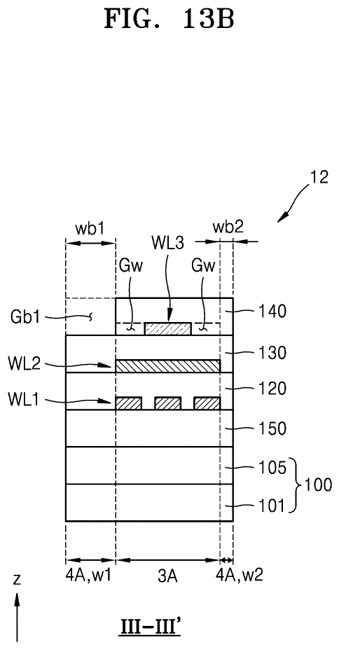

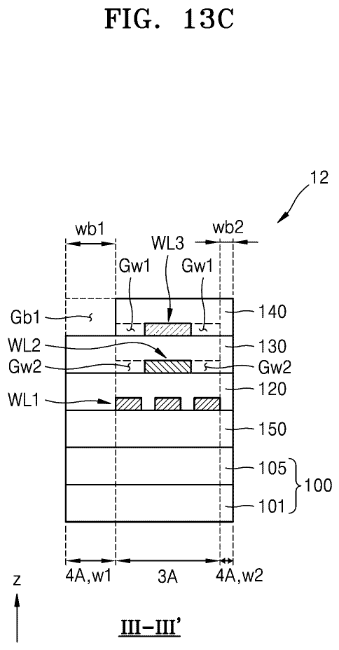

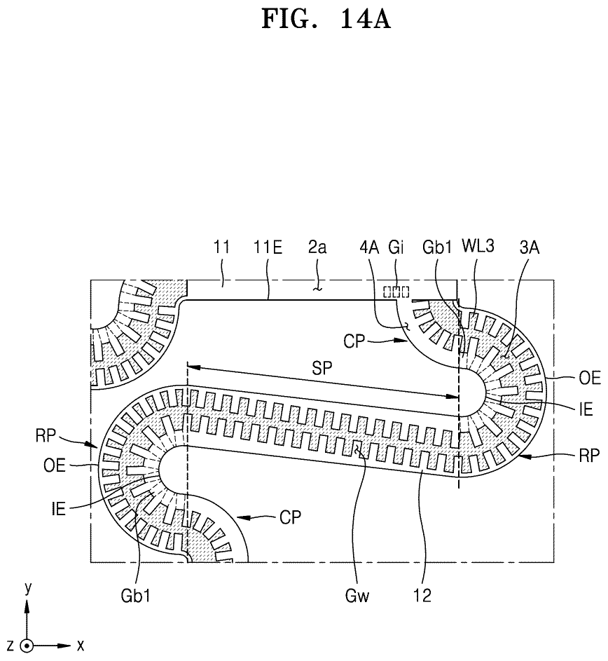

FIG. 13A is a schematic plan view of one first bridge portion 12 and an area adjacent to the first bridge portion 12 which are included in a display apparatus according to an embodiment. Also, FIGS. 13B and 13C are each a schematic cross-sectional view of the first bridge portion 12 according to an embodiment.

Referring to FIGS. 13A to 13C, in an embodiment, the first bridge portion 12 may include two round portions RPs, two connection portions CPs, and a straight-line portion SP between the round portions RPs. Each of the connection portions CP may be arranged between the round portion RP and the first island portion 11.

Each of the two round portions RPs may have an inner edge IE and an outer edge OE. The inner edge IE may extend along an arc of an imaginary circle having a first radius. The outer edge OE may extend along an arc of an imaginary circle having a second radius which is greater than the first radius.

The first bridge portion 12 may include a third area 3A and a fourth area 4A. The third area 3A may be defined as an area where the first line portion WL1, the second line portion WL2, and the third line portion WL3 are arranged, and the fourth areas 4A may be defined as areas between the third area 3A and both opposing side edges of the first bridge portion 12. In an embodiment, for example, two fourth areas 4A may be arranged with the third area 3A therebetween.

In the fourth area 4A of the first bridge portion 12, first groove patterns Gb1 that are open in a direction toward an upper surface (a surface in a +z direction) of the first bridge portion 12 may be arranged along the inner edge IE of each round portion RP. In a plan view, the first groove patterns Gb1 may have various shapes, such as polygonal shapes, semicircular shapes, amorphous shapes, etc.

According to an embodiment, as illustrated in FIG. 13B, fourth groove patterns Gw may be defined by the third line portion WL3. In an embodiment, for example, the fourth groove patterns Gw may be openings defined by removing a portion of the third line portion WL3. In a plan view, each of the fourth groove patterns Gw may have an open side while being in contact with an edge of the third line portion WL3. The fourth groove patterns Gw may have various shapes, such as polygonal shapes such as square shapes or triangular shapes, semicircular shapes, amorphous shapes, etc.

According to an embodiment, the fourth groove patterns Gw may be defined in at least one of lines included in the first line portion WL1, the second line portion WL2, and the third line portion WL3. In an embodiment, for example, as illustrated in FIG. 13C, first fourth groove patterns Gw1 may be defined by the third line potion WL3, and second fourth groove patterns Gw2 may be defined by the second line portion WL2. According to another embodiment, third fourth groove patterns may be defined in the first line portion WL1.

The fourth groove patterns Gw may be arranged in a line having a relatively greater width than other lines. In an embodiment, for example, the fourth groove patterns Gw may be arranged in a voltage line (for example, a driving voltage line, an initialization voltage line, etc.) configured to provide a voltage. A line having a small width (for example, a signal line, such as a gate line, a data line, etc.) may have a sufficient elongation rate without the fourth groove patterns Gw arranged.

In a plan view, an edge of the line portion defining the fourth groove patterns Gw may have a concavo-convex portion having a zigzag shape. FIG. 13A illustrates that both opposing side edges the third line portion WL3 may have the concavo-convex portion. However, the disclosure is not limited thereto. According to another embodiment, the fourth groove patterns Gw may be arranged along one side edge of the line portion. In such an embodiment, only the one side edge of the line portion may have a concavo-convex portion having a zigzag shape. When the first bridge portion 12 is shrunk or stretched, the fourth groove patterns Gw may distribute stress concentrated at a portion of a line.

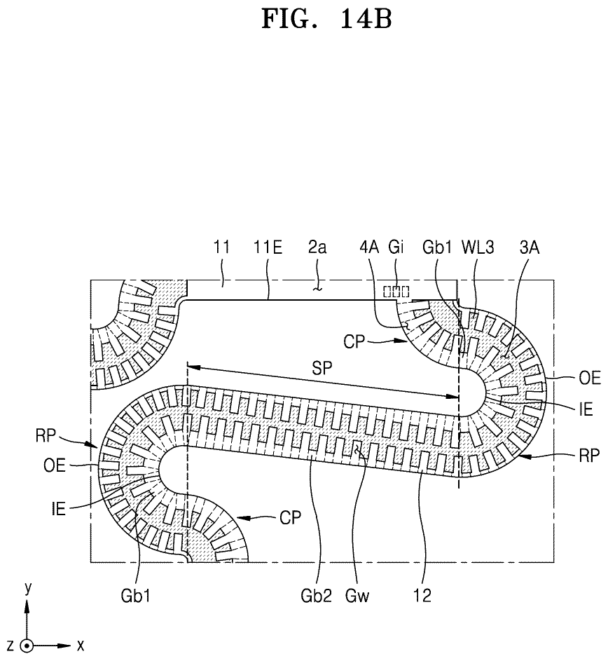

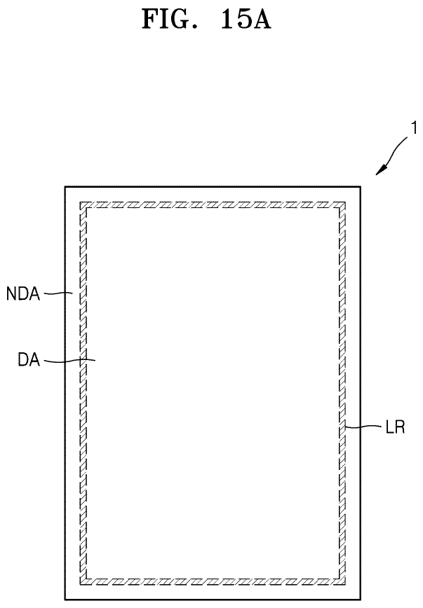

FIGS. 14A and 14B are plan views of one first bridge portion 12 and an area adjacent to the first bridge portion 12 which are included in a display apparatus according to an embodiment.

Referring to FIGS. 14A and 14B, an embodiment of the display apparatus may include one or more from among first groove patterns Gb1, second groove patterns Gi, third groove patterns Gb2, and fourth groove patterns Gw.

The display apparatus may include the first island portion 11 and the first bridge portion 12. The first bridge portion 12 may include two round portions RPs, two connection potions CPs, and a straight-line portion SP between the round portions RPs. Each of the connection portions CPs may be arranged between the round portion RP and the first island portion 11.

The first bridge portion 12 may include a third area 3A and fourth areas 4A arranged at both opposing sides of the third area 3A. In the fourth area 4A of the first bridge portion 12, the first groove patterns Gb1 that are open in a direction toward an upper surface (a surface in a +z direction) of the first bridge portion 12 may be arranged along the inner edge IE of each round portion RP.

In an embodiment, as illustrated in FIG. 14A, in the first island portion 11, the second groove patterns Gi that are open in a direction toward an upper surface (a surface in the +z direction) of the first island portion 11 may be arranged to be adjacent to the first bridge portion 12. The second groove patterns Gi may be arranged along an edge of the first island portion 11.

In the third area 3A of the first island portion 11, the third line portion WL3 may be arranged, and the fourth groove patterns Gw may be defined by the third line portion WL3. In a plan view, an edge of the third line portion WL3 may have a concavo-convex portion having a zigzag shape.

In an embodiment, as illustrated in FIG. 14B, in the fourth area 4A of the first bridge portion 12, the first groove patterns Gb1 may be arranged and the third groove patterns Gb2 that are open in the direction toward the upper surface of the first bridge portion 12 may further be arranged along the outer edge OE of each round portion RP, an edge of the connection portion CP, and both opposing side edges of the straight-line portion SP. Each of the first groove patterns Gb1 and each of the third groove patterns Gb2 may be wide patterns each having a first length l1 in an extension direction of the first bridge portion 12 or narrow patterns each having a third length l3 in the extension direction of the first bridge portion 12. A length (a width) of each of the first groove patterns Gb1 in the extension direction of the first bridge portion 12 may be the same as or different from a length (a width) of each of the third groove patterns Gb2 in the extension direction of the first bridge portion 12. The second groove patterns Gi may be wide patterns each having a second length l2 in a direction parallel with an edge of the first island portion 11 or narrow patterns each having a fourth length l4 in the direction parallel with the edge of the first island portion 11.

According to another embodiment, the second groove patterns Gi may be omitted, and only the first groove patterns Gb1 and the third groove patterns Gb2 may be arranged along both opposing side edges of the first bridge portion 12.

In embodiments of the disclosure, as described above, by changing lengths, depths, planar shapes, etc. of the first groove patterns Gb1, the second groove patterns Gi, the third groove patterns Gb2, and the fourth groove patterns Gw or by omitting some of the first groove patterns Gb1, the second groove patterns Gi, the third groove patterns Gb2, and the fourth groove patterns Gw, elongation rates of the first island portion 11 and the first bridge portion 12 may be adjusted. According to a shape and an elongation direction of a display apparatus, stress may be concentrated at some portions of the display apparatus. According to the embodiments described above, the first groove patterns Gb1, the second groove patterns Gi, the third groove patterns Gb2, and/or the fourth groove patterns Gw may be formed such that an elongation rate of a portion at which stress is concentrated may be greater than elongation rates of peripheral areas, thereby distributing the stress.

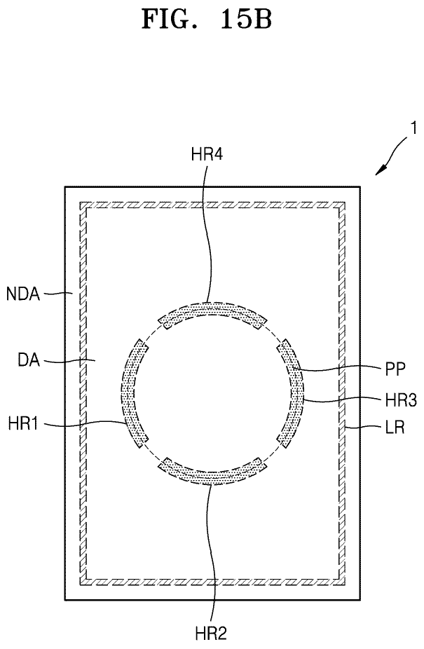

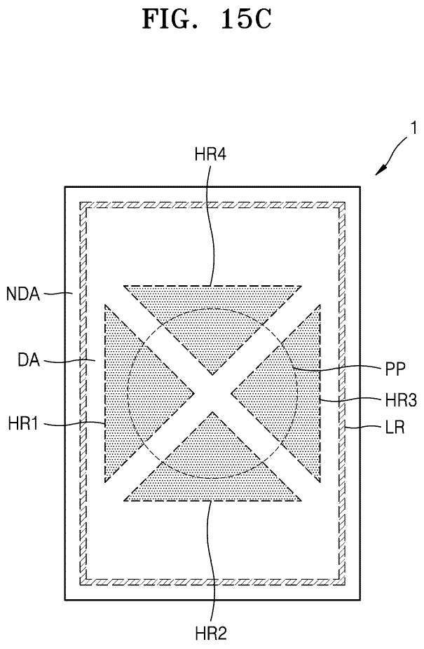

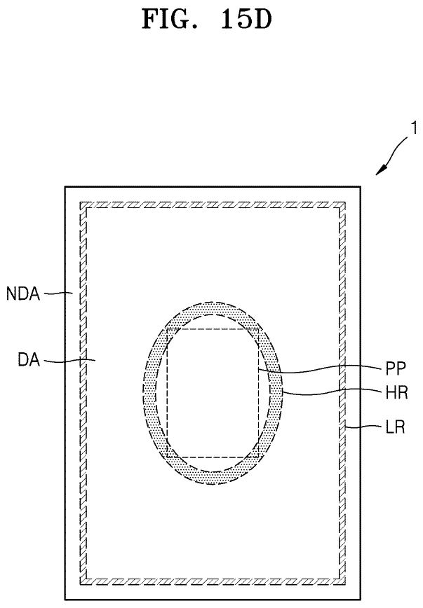

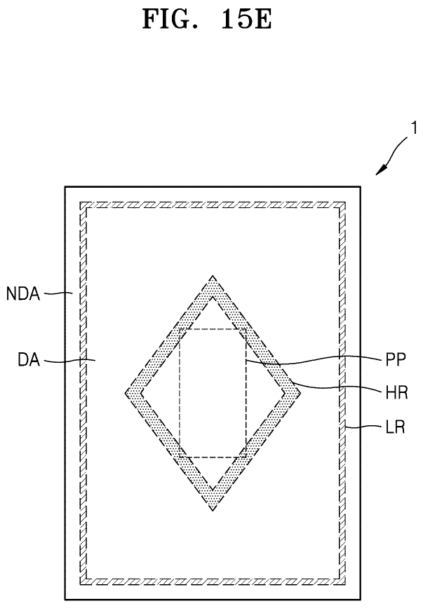

FIGS. 15A to 15E are schematic plan views of the display apparatus 1 according to an embodiment.

Referring to FIGS. 15A to 15E, an embodiment of the display apparatus 1 may include a display area DA and a non-display area NDA outside the display area DA. The display area DA may be where a plurality of pixels are included. The non-display area NDA is an area in which pixels are not arranged, and the non-display area NDA may entirely surround the display area DA.

In an embodiment, as described with reference to FIG. 4, the display area DA and the non-display area NDA may include the island portions and the bridge portions, where the island portions may be apart from each other in the first direction (for example, the x direction or the −x direction) and the second direction (for example, the y direction or the −y direction) and the bridge portions may connect the island portions. In an embodiment, for example, the display area DA may include the first island portions 11 in which the pixel driving circuit portions and the display elements are arranged and the first bridge portions 12 connecting the first island portions 11 adjacent to each other. The non-display area NDA may include the second island portions 21 in which the gate driving circuit and/or the data driving circuit are/is arranged and the second bridge portions 22 connecting the second island portions 21 adjacent to each other. Shapes of the second island portions 21 and the second bridge portions 22 may be substantially the same as shapes of the first island portions 11 and the first bridge portions 12 described above, but sizes and areas of the second island portions 21 and the second bridge portions 22 may be different from sizes and areas of the first island portions 11 and the first bridge portions 12. The second island portion 21 and the second bridge portion 22 may include groove patterns which are the same as or substantially the same as the groove patterns described above with reference to FIGS. 8A to 14B.

The display apparatus 1 may have a different elongation rate for each area. In an embodiment, for example, the elongation rate of the display area DA may be the same as or greater than the elongation rate of the non-display area NDA. The elongation rate of each area may be adjusted by the groove patterns. The groove patterns arranged in areas having different elongation rates from each other may have different shapes from each other. Here, that the groove patterns may have the different shapes from each other may denote that one or more from among types, widths, lengths, depths, and planar shapes of the groove patterns may be different between the groove patterns.

In an embodiment, for example, an area having a relatively greater elongation rate than other areas may have a greater number of groove patterns per unit area than the other areas or may have groove patterns having greater lengths than groove patterns of the other areas. Alternatively, an area having a relatively greater elongation rate than the other areas may include all of the first groove patterns Gb1, the second groove patterns Gi, the third groove patterns Gb2, and the fourth groove patterns Gw, and an area having a relatively less elongation rate than other areas may omit some of the first groove patterns Gb1, the second groove patterns Gi, the third groove patterns Gb2, and the fourth groove patterns Gw. An area having a low elongation rate may not include the groove patterns.

In an embodiment, as illustrated in FIG. 15A, the display apparatus 1 may include a low-elongation rate area LR having a relatively less elongation rate than peripheral areas. According to an embodiment, the low-elongation rate area LR may be arranged along a boundary between the non-display area NDA and the display area DA.

In an embodiment, as described with reference to FIG. 4, the non-display area NDA may include the first sub-non-display area SNDA1 in which the second island portions 21 and the second bridge portions 22 described above are arranged and the second sub-non-display area SNDA2 between the first sub-non-display area SNDA1 and the display area DA. The low-elongation rate area LR may be where the second sub-non-display area SNDA2 is included.

The third bridge portions 23 for connecting the display area DA with the first sub-non-display area SNDA1 may be arranged in the second sub-non-display area SNDA2. The third bridge portions 23 may be easily disconnected due to a difference in elongation rate between the first sub-non-display area SNDA1 and the display area DA. Thus, the groove patterns may not be arranged in the third bridge portions 23, or a less number of groove patterns may be arranged in the third bridge portions 23 than in the first bridge portions 12 and the second bridge portions 22.

According to an embodiment, the display apparatus 1 may include a high elongation rate area HR having a relatively greater elongation rate than peripheral areas and the low-elongation rate area LR having a relatively less elongation rate than the peripheral areas.

In an embodiment, as described above with reference to FIG. 2E, a portion of the display area DA may protrude in the third direction (for example, the z direction or the −z direction). The protruding portion of the display area DA may function as a button configured to display a certain image.

FIGS. 15B and 15C illustrate that a semicircular-shaped protrusion portion PP may be arranged in the center of the display area DA.

According to an embodiment, as illustrated in FIG. 15B, the display area DA may include four high-elongation rate areas HRs each having an arc shape, along an edge of the protrusion portion PP. According to another embodiment, the high-elongation rate areas HR may have a closed-loop shape surrounding the protrusion portion PP. According to another embodiment, as illustrated in FIG. 15C, the display area DA may include four high-elongation rate areas HRs each having a triangular shape having one vertex toward the center of the protrusion portion PP and having an opposite of the vertex, which is parallel with an edge of the display area DA.

The arrangement of the high-elongation rate areas HRs illustrated in FIGS. 15B and 15C may effectively distribute stress concentrated at areas respectively adjacent to a left (a −x direction) edge, a right (an x direction) edge, an upper (a y direction) edge, and a lower (a −y direction) edge of the semicircular-shaped protrusion portion PP.

FIGS. 15D and 15E illustrate embodiments where an approximately hexahedral-shaped protrusion portion PP may be arranged at the center of the display area DA. According to an embodiment, as illustrated in FIG. 15D, the display area DA may include a high-elongation rate area HR having a closed-circular loop shape surrounding the protrusion portion PP. According to an embodiment, as illustrated in FIG. 15E, the display area DA may include a high-elongation rate area HR having a closed-diamond shape surrounding the protrusion portion PP.

The protrusion potion PP may have various shapes in addition to a semicircular shape, a hexahedral shape, etc. According to the shape of the protrusion portion PP, the arrangement of the high-elongation rate area HR may be variously changed.

The display apparatus 1 according to the embodiments described above may be used for various electronic devices capable of providing an image. Here, the electronic device may indicate a device using electricity and capable of providing a certain image.

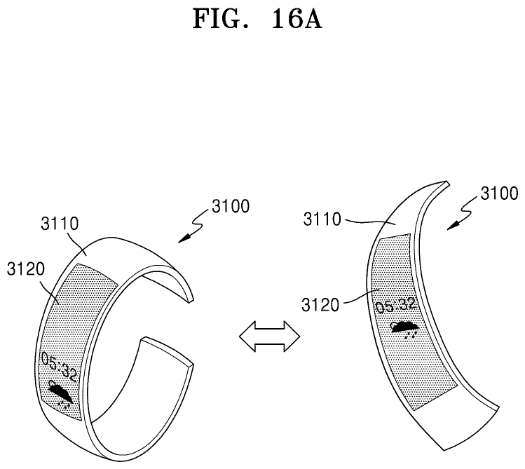

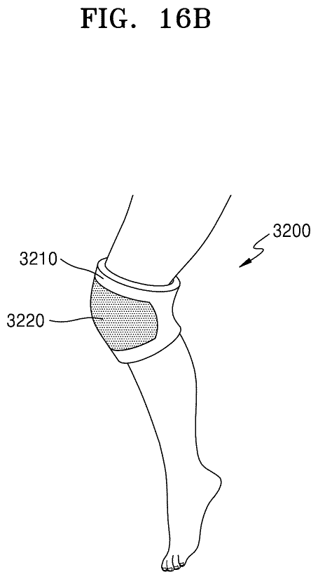

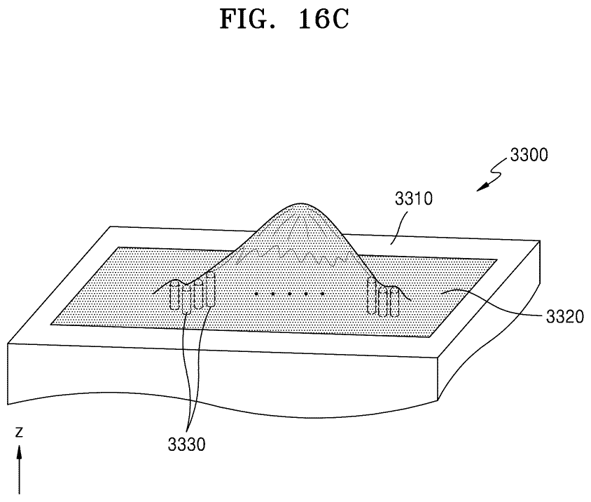

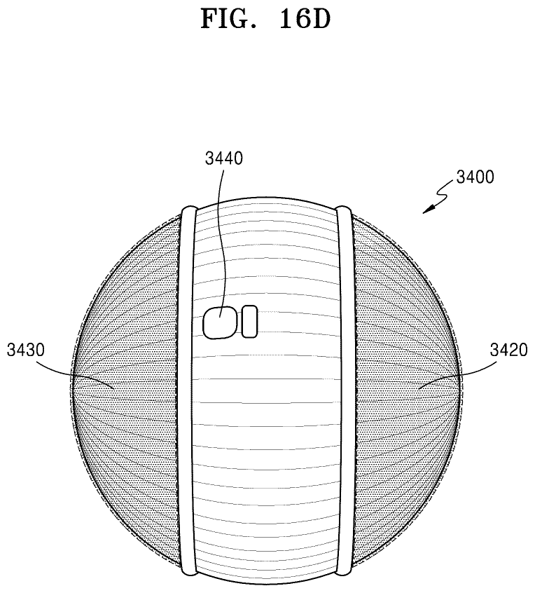

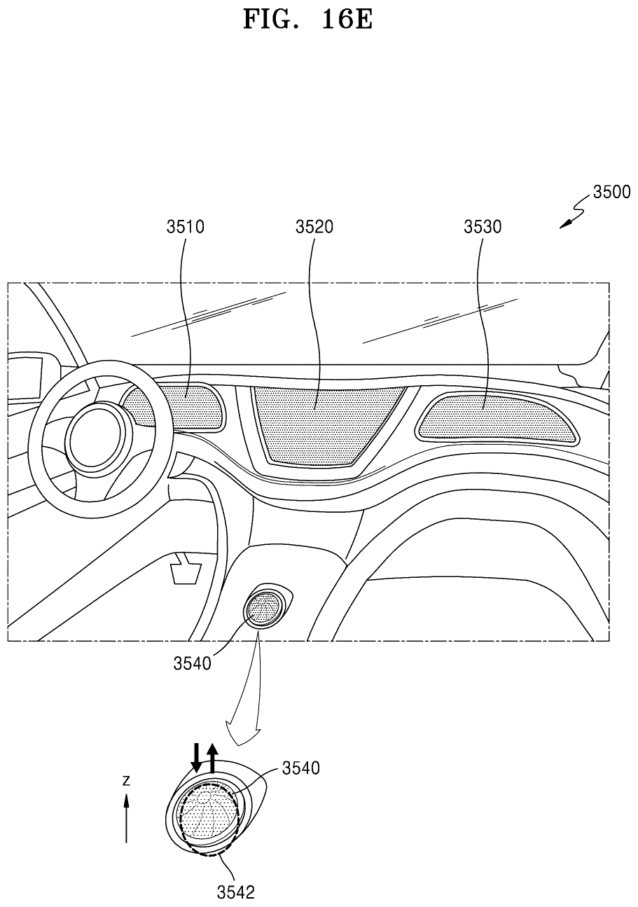

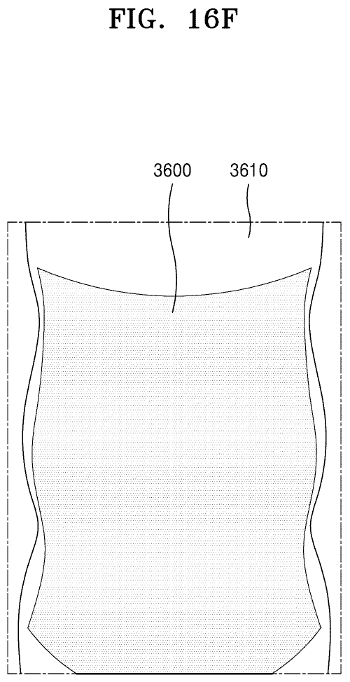

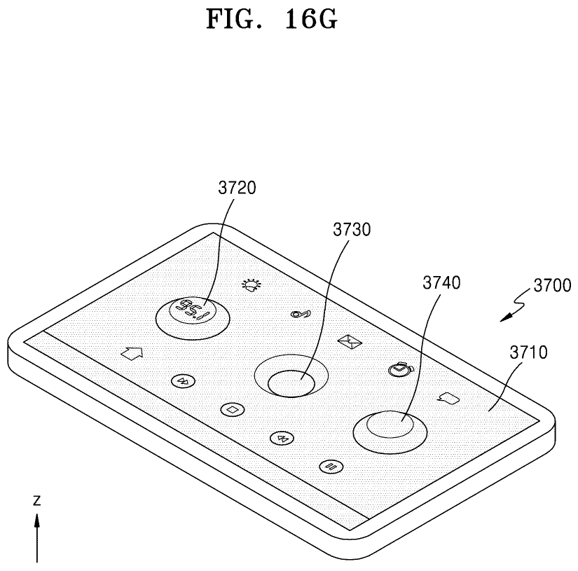

FIGS. 16A to 16G are each a schematic perspective view of an example of an electronic device including a display apparatus according to an embodiment.

Referring to FIG. 16A, the display apparatus according to an embodiment may be used for a wearable electronic device 3100 which may be worn on a part of a human body of a user. The wearable electronic device 3100 may include a body 3110 and a display 3120 provided in the body 3110. The display apparatus according to embodiments may be used as the display 3120 of the wearable electronic device 3100. The wearable electronic device 3100 may be transformed, as illustrated in FIG. 16A. According to an embodiment, according to selection of a user, the wearable electronic device 3100 may be used as a smart watch or a smartphone.

FIG. 16B illustrates an embodiment where the display apparatus is a medical electronic device 3200. According to an embodiment, the medical electronic device 3200 may include a body 3210 and an emission portion 3220. The display apparatus according to embodiments may be used as the emission portion 3220 of the medical electronic device 3200. The emission portion 3220 may emit light of a certain wavelength band (for example, infrared rays, visible rays, etc.) to a human body of a patient. According to an embodiment, the body 3210 may include a flexible fiber material and may have a structure that is wearable on a human body of a user of the emission portion.

FIG. 16C illustrates an embodiment where the display apparatus is an educational electronic device 3300. According to an embodiment, the educational electronic device may include a display 3320 provided in a frame 3310. The display 3320 may use the display apparatus according to embodiments. An image such as the sea swelling with waves, mountains covered with snow, volcanoes with flowing flames, or the like may be provided through the display 3320, and in this case, the display 3320 may be stretched in a height direction (for example, a z direction) by reflecting the height of the waves, mountains, or volcanoes. According to some embodiments, a portion of the display 3320 may have a height that is sequentially variable along a direction in which the flames flow, thereby three-dimensionally showing the movement of the flames. The educational electronic device 3300 may include a plurality of pins (or strokes) 3330 arranged at a rear surface of the display 3320 so that the display 3320 may be stretched in a height direction. As the pins 3330 move in a third direction (for example, the z direction or a −z direction), an image represented by the display 3320 may be realized to have a three-dimensional height. FIG. 16C illustrates an embodiment where the display apparatus is the educational electronic device 3300. However, the described usage is not limited thereto and may be applied to all devices providing certain image information.

It Embodiments of the electronic devices illustrated in FIGS. 16A to 16C may have variable shapes. However, the disclosure is not limited thereto. According to embodiments, as described below, the display apparatus according to embodiments may be used for an electronic device having a fixed portion (for example, a screen) configured to display an image.

FIG. 16D illustrates an embodiment where the display apparatus is a robot 3400. The robot 3400 may recognize a movement or an object by using a camera 3440 and may display a certain image for a user through displays 3420 and 3430. According to some embodiments, the display apparatus according to embodiments may be stretched in various directions as described above, and thus, may be assembled into a body frame having a semicircular shape. Thus, the robot 3400 may include the displays 3420 and 3430 having semicircular shapes.

FIG. 16E illustrates an embodiment where the display apparatus is a vehicle display device 3500. The vehicle display device 3500 may include a cluster 3510, a center information display (CID) 3520, and/or a co-driver display 3530. The display apparatus according to embodiments may be stretched in various directions, and thus, may not be limited by the shape of an internal frame of a vehicle and may be used for the cluster 3510, the CID 3520, and/or the co-driver display 3530.

FIG. 16E illustrates an embodiment where the cluster 3510, the CID 3520, and/or the co-driver display 3530 are separate devices from each other. However, the disclosure is not limited thereto. According to another embodiment, two or more selected from among the cluster 3510, the CID 3520, and the co-driver display 3530 may be integrally connected.

According to some embodiments, the vehicle display device 3500 may include a button 3540 configured to display a certain image. With reference to an enlarged view of FIG. 16E, the button 3540 having a semicircular shape may include an object 3542 providing a sense of use of a button by moving in a z direction or a −z direction and a display apparatus disposed above the object 3542. According some embodiments, when the object 3542 has a three-dimensionally round surface, the display apparatus may also have a three-dimensionally round surface.

FIG. 16F illustrates the electronic device according to an embodiment corresponding to an electronic device 3600 for advertisement or exhibition. According to some embodiments, the electronic device 3600 for advertisement or exhibition may be mounted on a structure 3610 that is fixed, such as a wall or a pillar. When the structure 3610 includes a concavo-convex surface as illustrated in FIG. 16F, the electronic device 3600 for advertisement or exhibition may also be arranged along the concavo-convex surface of the structure 3610. According to some embodiments, the electronic device 3600 for advertisement or exhibition may be mounted on the structure 3610 by using a thermal contraction film, etc.

FIG. 16G illustrates the electronic device according to an embodiment corresponding to a controller 3700. The controller 3700 may include an image-type button. In an embodiment, for example, the controller 3700 may include first to third button areas 3720, 3730, and 3740 in which portions of a display 3710, protrude in a z direction or protrude in a −z direction (or are recessed from the z direction). According to some embodiments, the first and third button areas 3720 and 3740 may protrude in the z direction, and the second button area 3730 may protrude in the −z direction (or may be recessed from the z direction).

According to an embodiment, a display apparatus capable of preventing damage due to stress concentration and capable of being stretched and shrunk in various directions may be provided.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display apparatus comprising:
a substrate including island areas and bridge areas, wherein each of the bridge areas has a serpentine shape and connects adjacent island areas to each other;
a first line arranged in each of the bridge area; and
a first insulating layer disposed on the first line,
wherein groove patterns are defined in the bridge areas by the first insulating layer.

2. The display apparatus of claim 1, wherein each of the bridge areas includes:
two round portions;
a straight-line portion between the two round portions; and
connection portions between the two round portions and the island areas.

3. The display apparatus of claim 2, wherein each of the two round portions includes an inner edge and an outer edge, and
the groove patterns include first groove patterns arranged along the inner edge.

4. The display apparatus of claim 3, further comprising:
a second insulating layer arranged in the island areas,
wherein second groove patterns are defined in the island areas by the second insulating layer to be adjacent to the bridge areas.

5. The display apparatus of claim 4, wherein the second groove patterns are arranged along an edge of the island area.

6. The display apparatus of claim 3, wherein the groove patterns further include third groove patterns arranged in the straight-line portion and the connection portions.

7. The display apparatus of claim 6, wherein the third groove patterns are arranged along both opposing side edges of the bridge area.

8. The display apparatus of claim 6, wherein each of the first groove patterns has a first width in an extension direction of the bridge area,
each of the third groove patterns has a second width in the extension direction of the bridge area, and
the first width is different from the second width.

9. The display apparatus of claim 2, wherein each of the two round portions includes an inner edge and an outer edge, and
the first line is arranged to be closer to the outer edge than to the inner edge.

10. The display apparatus of claim 1, further comprising:
a third insulating layer disposed below the first line,
wherein each of the groove patterns is defined by an opening defined in the first insulating layer and an opening defined in the third insulating layer.

11. The display apparatus of claim 10, wherein each of the groove patterns is defined by the opening defined in the first insulating layer, the opening defined in the third insulating layer, and an opening defined in the substrate.

12. The display apparatus of claim 1, wherein each of the groove patterns has a width in an extension direction of the bridge area, wherein the width increases as being toward an edge of the bridge area.

13. The display apparatus of claim 1, wherein each of the groove patterns has a width in an extension direction of the bridge area, wherein the width decreases as being toward an edge of the bridge area.

14. The display apparatus of claim 1, wherein, in a plan view, each of the groove patterns has a round edge.

15. The display apparatus of claim 1, wherein an edge of the first line has a concavo-convex portion.

16. The display apparatus of claim 15, further comprising:
a third insulating layer disposed below the first line; and
a second line disposed below the third insulating layer,
wherein an edge of the second line has a concavo-convex portion.

17. The display apparatus of claim 1, wherein the first insulating layer includes an organic insulating material or an inorganic insulating material.

18. A display apparatus including a display area and a non-display area outside the display area, the display apparatus comprising:
a substrate including island areas and bridge areas, wherein each of the bridge areas has a serpentine shape and connects adjacent island areas to each other;
a first line arranged in each of the bridge area; and
a first insulating layer disposed on the first line;
wherein groove patterns are defined in the bridge areas by the first insulating layer,
wherein groove patterns arranged in one of the bridge areas have different shapes from groove patterns arranged in another of the bridge areas.

19. The display apparatus of claim 18, wherein the non-display area includes a first sub-non-display area and a second sub-non-display area between the first sub-non-display area and the display area, and
an elongation rate of the first sub-non-display area is greater than an elongation rate of the second sub-non-display area.

20. The display apparatus of claim 18, wherein an elongation rate of the display area is equal to or greater than an elongation rate of the non-display area.

21. The display apparatus of claim 18, wherein the display area includes at least one first area and a second area outside the at least one first area, and
an elongation rate of the at least one first area is greater than an elongation rate of the second area.

22. The display apparatus of claim 21, wherein an edge of the first line has a concavo-convex portion in the at least one first area.

23. The display apparatus of claim 21, wherein the display area has a protrusion portion protruding from a peripheral portion in a thickness direction, and
the at least one first area is arranged to surround at least a portion of the protrusion portion.

24. The display apparatus of claim 23, wherein the at least one first area has a loop shape surrounding the protrusion portion.

25. The display apparatus of claim 23, wherein the at least one first area has a triangular shape having one vertex toward a center of the protrusion portion.
